(19) United States
(12) Patent Application Publication
(10) Pub. No.: US 2026/0243600 A1
(43) Pub. Date: Aug. 20, 2026

(54) LIGHT DETECTION CIRCUIT

(71) Applicant: HAMAMATSU PHOTONICS K.K., Hamamatsu-shi, Shizuoka (JP)

(72) Inventor: Fumiya NAITO, Shizuoka (JP)

(73) Assignee: HAMAMATSU PHOTONICS K.K., Hamamatsu-shi, Shizuoka (JP)

(21) Appl. No.: 19/159,846

(22) PCT Filed: Jan. 9, 2024
(86) PCT No.: PCT/JP2024/000186

§ 371 Date: Aug. 26, 2025

(30) Foreign Application Priority Data
Feb. 27, 2023 (JP) 2023-028247

(51) Int. Cl. G01J 1/46

(52) U.S. Cl. CPC G01J 1/46

(57) ABSTRACT

This photodetection circuit comprises: a photodetection photodetector that outputs a signal current; a current-to-voltage converter that converts the signal current into a first signal voltage; a first current removal circuit that extracts a first current from the signal current; and a second current removal that extracts a second current from the signal current. The first current removal circuit determines the level of the first current based on the level of a low-frequency component at a prescribed timing, and maintains the level of the first current. The second current removal circuit has a feedback circuit, a smoothing capacitor, and a second transistor. The feedback circuit part outputs a second signal voltage of a level in accordance with the first signal voltage. The smoothing capacitor smooths the second signal voltage. The second transistor extracts, from the signal current, a second current of a level corresponding to the smoothed second signal voltage.

### TECHNICAL FIELD

The present disclosure relates to a photodetection circuit. This application is based upon and claims the benefit of priority from Japanese Patent Application No. 2023-028247 filed on Feb. 27, 2023, the entire contents of which are incorporated herein by reference.

### Background Art

Patent Literature 1 discloses a photodetection circuit. The photodetection circuit includes a position sensing device (PSD), a current-to-voltage conversion circuit, and a removal circuit. The current-to-voltage conversion circuit converts the signal current output from the position sensing device into a signal voltage. The removal circuit removes a steady-state component contained in the signal current based on a steady-state component contained in the signal voltage.

### PRIOR ART DOCUMENTS

### Patent Literature

Patent Literature 1: Japanese Unexamined Patent Publication No. H4-142416

### SUMMARY OF THE INVENTION

### Problems to be Solved by the Invention

For example, when detecting light using a photodetection element such as a photodiode, a low-frequency component contained in a signal current output from the photodetection element may be removed from the signal current. The low-frequency component is, for example, a current component due to background light and/or a dark current component. FIG. 21 is a diagram showing a reference example of a photodetection circuit having a function of removing a low-frequency component from a signal current. A photodetection circuit 100 shown in the figure includes a photodetection element 101, a current-to-voltage conversion circuit 102 connected to the photodetection element 101, an amplifier 103 for feedback, a smoothing capacitor 104 for smoothing, and a transistor 105. The current-to-voltage conversion circuit 102 is a charge-type amplifier having an amplifier 106 and a capacitor 107, and converts a signal current output from the photodetection element 101 into a signal voltage. The amplifier 103 amplifies a difference between a voltage on the input side and a voltage on the output side of the current-to-voltage conversion circuit 102 and outputs the amplified difference. The smoothing capacitor 104 smooths the output voltage from the amplifier 103. The smoothed output voltage is input to the gate of the transistor 105. The transistor 105 extracts a low-frequency component contained in the signal current output from the photodetection element 101 from the signal current in response to a voltage applied to its gate.

However, the circuit 100 shown in FIG. 21 has the following problems. The greater the low-frequency component to be removed, the greater the transconductance of the transistor 105, resulting in an increase in loop gain. As a result, the frequency band of the low-frequency component extracted from the signal current expands. Therefore, there is a risk that a signal component that should not be extracted will also be extracted. In order to avoid such a problem, the capacitance of the smoothing capacitor 104 may be increased, but this would increase the time required for the charge to accumulate in the smoothing capacitor 104. Therefore, when the photodetection circuit 100 operates intermittently, a long settling time is required for the feedback operation every time the photodetection circuit 100 transitions from a non-operating state to an operating state. Thus, there is a trade-off between keeping the frequency band of the low-frequency component extracted from the signal current small and shortening the settling time of the feedback operation.

It is an object of the present disclosure to provide a photodetection circuit that can shorten the settling time of the feedback operation while keeping the frequency band of the low-frequency component extracted from the signal current small.

### Means for Solving the Problem

[1] A photodetection circuit according to one aspect of the present disclosure includes a photodetection element, a current-to-voltage conversion unit, a first current removal unit, and a second current removal unit. The photodetection element is configured to output a signal current in response to incidence of signal light. The current-to-voltage conversion unit has a signal input terminal and a signal output terminal and is configured to convert the signal current input to the signal input terminal into a first signal voltage and output the first signal voltage from the signal output terminal, the signal input terminal being connected to the photodetection element. The first current removal unit is connected to the photodetection element, and is configured to extract a first current from the signal current. The second current removal unit is connected to the photodetection element, and is configured to extract a second current from the signal current. The signal current includes a signal component and a low-frequency component having a lower frequency than the signal component or having a constant magnitude. The first current removal unit is configured to determine a magnitude of the first current based on the magnitude of the low-frequency component at a predetermined timing and to maintain the magnitude of the first current. The second current removal unit includes a feedback circuit section, a smoothing capacitor, and a second transistor. The feedback circuit section is connected to the signal output terminal of the current-to-voltage conversion unit, and is configured to output a second signal voltage having a magnitude corresponding to the first signal voltage. The smoothing capacitor is configured to smooth the second signal voltage. The second transistor is configured to extract, from the signal current, the second current having a magnitude corresponding to the second signal voltage smoothed by the smoothing capacitor.

According to the photodetection circuit according to [1] above, a certain portion (first current) of the low-frequency component contained in the signal current is extracted from the signal current by the first current removal unit. The remaining portion (second current) of the low-frequency component contained in the signal current is extracted from the signal current by the second current removal unit. The remaining portion is a fluctuation of the low-frequency component after a predetermined timing. With this configuration, a low-frequency component to be removed by the second current removal unit that performs a feedback operation of the low-frequency component is reduced, so that the transconductance of the second transistor is reduced and the loop gain is reduced. As a result, the frequency band of the low-frequency component extracted from the signal current in the second current removal unit, that is, the frequency band of the second current, becomes narrower. Since the charge to be accumulated in the smoothing capacitor is reduced, the time required to accumulate the charge in the smoothing capacitor is shortened. Therefore, the settling time of the feedback operation can be shortened. Thus, according to the photodetection circuit according to [1] above, it is possible to shorten the settling time of the feedback operation while keeping the frequency band of the low-frequency component extracted from the signal current small.
[2] In the photodetection circuit according to [1] above, the first current removal unit may include a voltage-holding capacitor, a first switching element, and a first transistor. The voltage-holding capacitor is configured to be charged by a current from the photodetection element. The first switching element is configured to switch on/off a flow of a current from the photodetection element to the voltage-holding capacitor. The first transistor has a control terminal, a first current terminal, and a second current terminal. A voltage based on a voltage across the voltage-holding capacitor is applied to the control terminal. The first current terminal is connected to the photodetection element. The second current terminal is connected to a constant potential line.

The photodetection circuit according to [2] above operates, for example, as follows. First, in a period during which the first signal voltage output from the photodetection circuit is not used outside the photodetection circuit, the first switching element allows the signal current to flow from the photodetection element to the voltage-holding capacitor. As a result, the charge is accumulated in the voltage-holding capacitor to increase the voltage across the voltage-holding capacitor. At this time, since the voltage-holding capacitor allows a high frequency signal component contained in the signal current to pass therethrough, the voltage across the voltage-holding capacitor depends mainly on the magnitude of the low-frequency component contained in the signal current. Then, after the above-described predetermined timing at which the voltage across the voltage-holding capacitor stops changing, the first signal voltage output from the photodetection circuit is used outside the photodetection circuit. The first switching element switches at the predetermined timing so that no current flows from the photodetection element to the voltage-holding capacitor. As a result, the voltage across the voltage-holding capacitor is determined based on the magnitude of the low-frequency component at the predetermined timing, and is maintained at a constant value even after the predetermined timing. The voltage across the voltage-holding capacitor is applied to the control terminal of the first transistor, and the first transistor extracts, from the signal current, a first current having a magnitude corresponding to the voltage across the voltage-holding capacitor. Thus, according to the photodetection circuit according to [2] above, the magnitude of the first current can be determined based on the magnitude of the low-frequency component at a predetermined timing.
[3] In the photodetection circuit according to [2] above, the first switching element may be an amplifier having a control terminal for selecting whether or not to perform output. In this case, since the charge due to the signal current can be accumulated in the voltage-holding capacitor more quickly, the time required for charge accumulation can be shortened. The time required for the charge to accumulate in the voltage-holding capacitor is the time during which the first signal voltage corresponding to the light intensity of the signal light cannot be output, that is, the dead time. According to the photodetection circuit according to [3] above, it is possible to shorten the dead time. In addition, by providing the amplifier with a function of switching on/off the flow of a current from the photodetection element to the voltage-holding capacitor, the number of components can be further reduced.
[4] In the photodetection circuit according to [1] above, the first current removal unit may include a voltage-holding capacitor, a first resistance element, and a first transistor. The voltage-holding capacitor is configured to be charged by a current from the photodetection element. The first resistance element is provided on a path of a current flowing from the photodetection element to the voltage-holding capacitor. The first transistor has a control terminal, a first current terminal, and a second current terminal. A voltage based on a voltage across the voltage-holding capacitor is applied to the control terminal. The first current terminal is connected to the photodetection element. The second current terminal is connected to a constant potential line.

The photodetection circuit according to [4] above operates, for example, as follows. First, in a period during which the first signal voltage output from the photodetection circuit is not used outside the photodetection circuit, a part of the signal current flows from the photodetection element to the voltage-holding capacitor through the first resistance element. As a result, the charge is accumulated in the voltage-holding capacitor to increase the voltage across the voltage-holding capacitor. At this time, since the voltage-holding capacitor allows a high frequency signal component contained in the signal current to pass therethrough, the voltage across the voltage-holding capacitor depends mainly on the magnitude of the low-frequency component contained in the signal current. Then, after the predetermined timing at which the voltage across the voltage-holding capacitor stops changing, the first signal voltage output from the photodetection circuit is used outside the photodetection circuit. If the period is sufficiently short, the voltage across the voltage-holding capacitor is determined based on the magnitude of the low-frequency component at the predetermined timing and is maintained at an approximately constant value during that period. The voltage across the voltage-holding capacitor is applied to the control terminal of the first transistor, and the first transistor extracts, from the signal current, a first current having a magnitude corresponding to the voltage across the voltage-holding capacitor. Thus, according to the photodetection circuit according to [4] above, the magnitude of the first current can be determined based on the magnitude of the low-frequency component at a predetermined timing.
[5] In the photodetection circuit according to [2] or [4] above, the first current removal unit may further include a first amplifier configured to amplify a current flowing from the photodetection element to the voltage-holding capacitor or a voltage applied from the photodetection element to the voltage-holding capacitor. In this case, since the charge due to the signal current can be accumulated in the voltage-holding capacitor more quickly, the time required for charge accumulation can be shortened. The time required for the charge to accumulate in the voltage-holding capacitor is the time during which the first signal voltage corresponding to the light intensity of the signal light cannot be output, that is, the dead time. According to the photodetection circuit according to [5] above, it is possible to shorten the dead time.
[6] In the photodetection circuit according to any one of [2] to above, the first current removal unit may further include a transistor. The transistor is connected in series with the first transistor between the photodetection element and a constant potential line. A voltage based on a voltage across the voltage-holding capacitor is applied to a control terminal of the transistor. In this case, it is possible to adjust the magnitude of the gate voltage required to turn on the first transistor.
[7] In the photodetection circuit according to any one of [2] to above, the first current removal unit may further include a first shorting switch connected in parallel with the voltage-holding capacitor. When the first current removal unit is not used, a pair of electrodes of the voltage-holding capacitor can be shorted through the first shorting switch to prevent the misoperation of the first transistor due to unnecessary accumulation of charge in the voltage-holding capacitor.
[8] In the photodetection circuit according to any one of [1] to above, the second current removal unit may further include a second switching element. The second switching element is connected in series between the photodetection element and the smoothing capacitor, and is configured to switch on/off a flow of a current from the photodetection element to the smoothing capacitor. The photodetection circuit operates, for example, as follows. First, in a period during which the first signal voltage output from the photodetection circuit is not used outside the photodetection circuit, the second switching element allows the signal current to flow from the photodetection element to the smoothing capacitor. As a result, the charge is accumulated in the smoothing capacitor to increase the voltage across the smoothing capacitor. Then, the first signal voltage output from the photodetection circuit is used outside the photodetection circuit. At this time, the second switching element is switched so that no current flows from the photodetection element to the smoothing capacitor. Then, the smoothing capacitor smooths the second signal voltage. Thus, according to the photodetection circuit according to [8], since the charge can be accumulated in advance in the smoothing capacitor before the first signal voltage is used outside the photodetection circuit, the settling time of the feedback operation in the second current removal unit can be further shortened.
[9] In the photodetection circuit according to [8] above, the feedback circuit section may include a second amplifier. The second amplifier has an input terminal and an output terminal. The input terminal of the second amplifier is connected to the signal output terminal of the current-to-voltage conversion unit. The output terminal of the second amplifier is connected to the smoothing capacitor. Then, the second amplifier may further have a control terminal for selecting whether or not to perform output. According to the photodetection circuit according to [9], when accumulating the charge in advance in the smoothing capacitor, the second amplifier is controlled so as not to perform output. Thus, this prevents a part of the current from the photodetection element from flowing into the second amplifier, the charge can be efficiently accumulated in the smoothing capacitor.
[10] In the photodetection circuit according to [8] above, the feedback circuit section may include a second amplifier. The second amplifier has an input terminal and an output terminal. The input terminal of the second amplifier is connected to the signal output terminal of the current-to-voltage conversion unit. The output terminal of the second amplifier is connected to the smoothing capacitor. The second current removal unit may further include a third switching element. The third switching element is connected in series between the second amplifier and the smoothing capacitor. The third switching element switches a relationship between the second amplifier and the smoothing capacitor between a connecting state and a disconnecting state. According to the photodetection circuit according to [10], when accumulating the charge in advance in the smoothing capacitor, the relationship between the second amplifier and the smoothing capacitor becomes a disconnecting state by the third switching element. As a result, this prevents a part of the current from the photodetection element from flowing out to the second amplifier, the charge can be efficiently accumulated in the smoothing capacitor.
[11] In the photodetection circuit according to [8] above, the feedback circuit section may include a second resistance element. The second resistance element includes one end and another end. The one end of the second resistance element is connected to the signal output terminal of the current-to-voltage conversion unit. The other end of the second resistance element is connected to the smoothing capacitor. The second current removal unit may further include a third switching element. The third switching element is connected in series with the second resistance element between the signal output terminal of the current-to-voltage conversion unit and the smoothing capacitor. The third switching element switches a relationship between the signal output terminal and the smoothing capacitor between a connecting state and a disconnecting state. According to the photodetection circuit according to [11], when accumulating the charge in advance in the smoothing capacitor, the relationship between the signal output terminal and the smoothing capacitor becomes a disconnecting state by the third switching element. Thus, this prevents a part of the current from the photodetection element from flowing out through the second resistance element, the charge can be efficiently accumulated in the smoothing capacitor.
[12] In the photodetection circuit according to [8] above, the second current removal unit may further include a third amplifier configured to amplify a current flowing from the photodetection element to the smoothing capacitor or a voltage applied from the photodetection element to the smoothing capacitor. In this case, since the accumulation of charge in the smoothing capacitor is accelerated, the settling time of the feedback operation in the second current removal unit can be further shortened.
[13] In the photodetection circuit according to [8] above, the second switching element may be an amplifier having a control terminal for selecting whether or not to perform output. In this case, the time required for the charge to accumulate in the smoothing capacitor can be shortened. The time required for the charge to accumulate in the smoothing capacitor is the time during which the first signal voltage corresponding to the light intensity of the signal light cannot be output, that is, the dead time. According to the photodetection circuit according to [13] above, it is possible to shorten the dead time. In addition, by providing the amplifier with a function of switching on/off the flow of a current from the photodetection element to the smoothing capacitor, the number of components can be further reduced.
[14] In the photodetection circuit according to [8] above, the current-to-voltage conversion unit may be configured to be able to switch on/off input of the signal current to the signal input terminal. According to the photodetection circuit according to [14], when accumulating the charge in advance in the smoothing capacitor, the current-to-voltage conversion unit is controlled so that no signal current is input to the signal input terminal. Thus, this prevents a part of the current from the photodetection element from flowing out to the current-to-voltage conversion unit, the charge can be efficiently accumulated in the smoothing capacitor.
[15] In the photodetection circuit according to [2] or [3] above, the second current removal unit may further include a second switching element connected in series between a node between the first switching element and the voltage-holding capacitor and the smoothing capacitor and configured to switch on/off a flow of a current from the photodetection element to the smoothing capacitor together with the first switching element.
[16] In the photodetection circuit according to [2] or [3] above, the second current removal unit may further include a second switching element connected in series between the photodetection element and the smoothing capacitor and configured to switch on/off a flow of a current from the photodetection element to the smoothing capacitor. The first switching element may be connected in series between a node between the second switching element and the smoothing capacitor and the voltage-holding capacitor, and may be configured to switch on/off a flow of a current from the photodetection element to the voltage-holding capacitor together with the second switching element.
[17] In the photodetection circuit according to any one of [1] to above, the second current removal unit may further include a second shorting switch connected in parallel with the smoothing capacitor. When the second current removal unit is not used, a pair of electrodes of the smoothing capacitor can be shorted through the second shorting switch to prevent the misoperation of the second transistor.

Advantageous Effects of Invention According to the present disclosure, it is possible to provide a photodetection circuit that can shorten the settling time of a feedback circuit while suppressing the expansion of the frequency band of components extracted from a signal current.

### BRIEF DESCRIPTION OF DRAWINGS

FIG. 1 is a circuit diagram showing the configuration of a photodetection circuit according to an embodiment.

FIG. 2 is a diagram showing the operation of a photodetection circuit.

FIG. 3 is a circuit diagram showing the configuration of a first current removal unit according to a modification.

FIG. 4 is a circuit diagram showing the configuration of a first current removal unit according to a modification.

FIG. 5 is a circuit diagram showing the configuration of a first current removal unit according to a modification.

FIG. 6 is a circuit diagram showing the configuration of a first current removal unit according to a modification.

FIG. 7 is a circuit diagram showing the configuration of a second current removal unit according to a modification.

FIG. 8 is a circuit diagram showing the configuration of a second current removal unit according to a modification.

FIG. 9 is a circuit diagram showing the configuration of a second current removal unit according to a modification.

FIG. 10 is a circuit diagram showing the configuration of a current-to-voltage conversion unit according to a modification.

FIG. 11 is a circuit diagram showing the configuration of a current-to-voltage conversion unit according to a modification.

FIG. 12 is a circuit diagram showing the configuration of a photodetection circuit according to a modification.

FIG. 13 is a circuit diagram showing the configuration of a second current removal unit according to a modification.

FIG. 14 is a circuit diagram showing the configuration of a photodetection circuit according to a modification.

FIG. 15 is a circuit diagram showing the configuration of a photodetection circuit according to a modification.

FIG. 16 is a circuit diagram showing the configuration of a photodetection circuit according to a modification.

FIG. 17 is a circuit diagram showing the configuration of a photodetection circuit according to a modification.

FIG. 18 is a circuit diagram showing the configuration of a photodetection circuit according to a modification.

FIG. 19 is a circuit diagram showing the configuration of a photodetection circuit according to a modification.

FIG. 20 is a circuit diagram showing the configuration of a photodetection circuit according to a modification.

FIG. 21 is a diagram showing a reference example of a photodetection circuit having a function of removing a low-frequency component from a signal current.

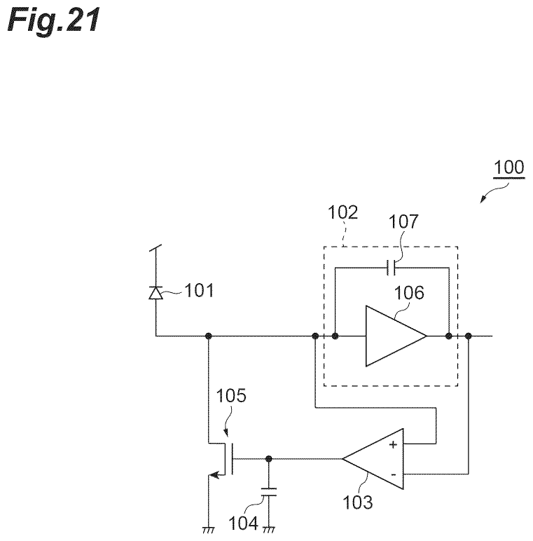

### DESCRIPTION OF EMBODIMENTS

Hereinafter, embodiments of a photodetection circuit according to the present disclosure will be described in detail with reference to the accompanying diagrams. In the description of the diagrams, the same elements are denoted by the same reference numerals, and the repeated description thereof will be omitted.

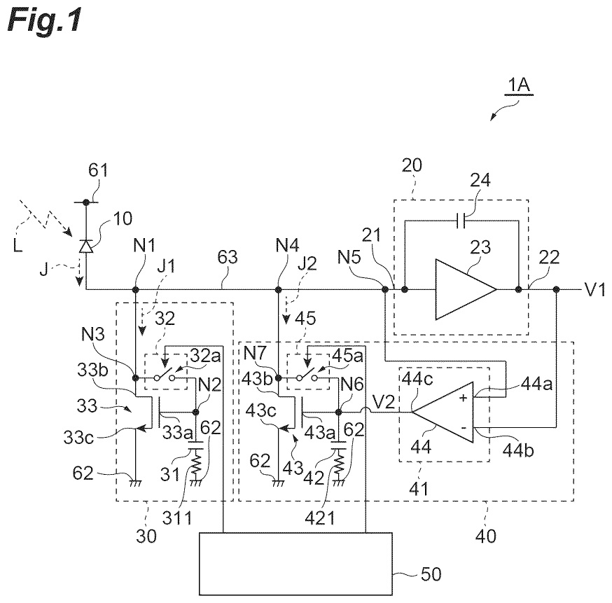

FIG. 1 is a circuit diagram showing the configuration of a photodetection circuit 1A according to an embodiment of the present disclosure. The photodetection circuit 1A receives signal light L from the outside and outputs a first signal voltage V1 according to the light intensity of the signal light L. As shown in FIG. 1, the photodetection circuit 1A according to the present embodiment includes a photodetection element 10, a current-to-voltage conversion unit 20, a first current removal unit 30, a second current removal unit 40, and a control unit 50.

The photodetection element 10 is, for example, a photodiode or a position sensing device (PSD). The photodetection element 10 may be one of a plurality of photodetection elements included in a photodetection element array. In this case, the photodetection circuit 1A is provided for each photodetection element. The signal light L is incident on the photodetection element 10. The photodetection element 10 outputs a signal current J according to the light intensity of the signal light L. When the photodetection element 10 is a photodiode, the cathode of the photodiode is connected to a bias line 61. The bias line 61 is a first constant potential line having a higher potential than a reference potential line 62. The reference potential line 62 is a second constant potential line having a lower potential than the bias line 61. The signal current J contains a signal component and a low-frequency component. The low-frequency component is a component having a lower frequency than the signal component or having a predetermined magnitude. The low-frequency component contains, for example, one or both of a current due to background light contained in the signal light L and a dark current generated in the photodetection element 10.

The current-to-voltage conversion unit 20 has a signal input terminal 21 and a signal output terminal 22. The signal input terminal 21 is connected to the photodetection element 10 through a wiring 63. When the photodetection element 10 is a photodiode, the signal input terminal 21 is connected to the anode of the photodiode. The current-to-voltage conversion unit 20 converts the signal current J input to the signal input terminal 21, more precisely, a current obtained by excluding a first current J1 and a second current J2, which will be described later, from the signal current J, into the first signal voltage V1. The current-to-voltage conversion unit 20 outputs the first signal voltage V1 from the signal output terminal 22. In one example, the current-to-voltage conversion unit 20 is a charge amplifier. The charge amplifier has an amplifier 23 and a capacitor 24. One end of the capacitor 24 is connected to the input terminal of the amplifier 23, and the other end of the capacitor 24 is connected to the output terminal of the amplifier 23. Alternatively, the current-to-voltage conversion unit 20 may be a transimpedance amplifier. The transimpedance amplifier has an amplifier and a resistor. One end of the resistor is connected to the input terminal of the amplifier, and the other end of the resistor is connected to the output terminal of the amplifier. The circuit configuration of the current-to-voltage conversion unit 20 is not limited to the charge amplifier and the transimpedance amplifier, but may be any of various circuit configurations capable of converting a current into a voltage.

The first current removal unit 30 is connected to the photodetection element 10, and removes the first current JI from the signal current J. In one example, the first current removal unit 30 is connected to a node N1 on the wiring 63 between the photodetection element 10 and the current-to-voltage conversion unit 20. The first current removal unit 30 is configured to determine the magnitude of the first current JI based on the magnitude of the low-frequency component of the signal current J at a predetermined timing and to maintain the magnitude of the first current J1.

The first current removal unit 30 in the present embodiment has a voltage-holding capacitor 31, a first switching element 32, and a first transistor 33. The voltage-holding capacitor 31 is configured to be charged by the current from the photodetection element 10. Specifically, one electrode of the voltage-holding capacitor 31 is connected to the photodetection element 10 through the first switching element 32 and the node N1. The other electrode of the voltage-holding capacitor 31 is connected to the reference potential line 62. The capacitance of the voltage-holding capacitor 31 is, for example, 100 fF or more and 1 pF or less. The type of the voltage-holding capacitor 31 is, for example, a MOS capacitor. The first switching element 32 is connected in series between the node N1 and the voltage-holding capacitor 31. The first switching element 32 switches on/off the flow of a current from the photodetection element 10 to the voltage-holding capacitor 31. In other words, the first switching element 32 switches the relationship between the photodetection element 10 and the voltage-holding capacitor 31 between a connecting state and a disconnecting state. The first switching element 32 in the present embodiment has a switch 32a. The switch 32a may be a mechanical switch or a semiconductor switch such as a transistor.

The first transistor 33 is configured to extract, from the signal current J, the first current J1 having a magnitude corresponding to the voltage across the voltage-holding capacitor 31. The first transistor 33 has a control terminal 33a (gate), a first current terminal 33b (drain), and a second current terminal 33c (source). The first transistor 33 in the present embodiment is an N-channel MOSFET (Metal-Oxide-Semiconductor Field-Effect Transistor). The control terminal 33a is connected to a node N2 between one electrode of the voltage-holding capacitor 31 and the first switching element 32. A voltage based on the voltage across the voltage-holding capacitor 31, for example, the voltage across the voltage-holding capacitor 31 itself, is applied to the control terminal 33a. The first current terminal 33b is connected to a node N3 between the first switching element 32 and the node N1, and is connected to the photodetection element 10 through the nodes N3 and N1. The second current terminal 33c is connected to the reference potential line 62.

Between the node N2 and the reference potential line 62, a resistance element 311 may be provided in series with the voltage-holding capacitor 31, or the resistance element 311 may not be provided. In each modification described below, the resistance element 311 may be similarly provided. In the shown example, the resistance element 311 is connected between the voltage-holding capacitor 31 and the reference potential line 62, but the resistance element 311 may be connected between the node N2 and the voltage-holding capacitor 31.

The second current removal unit 40 is connected to the photodetection element 10, and removes the second current J2 from the signal current J. In one example, the second current removal unit 40 is connected to a node N4 between the photodetection element 10 and the current-to-voltage conversion unit 20. The node N4 may be located between the node N1 and the current-to-voltage conversion unit 20, the node N1 may be located between the node N4 and the current-to-voltage conversion unit 20, or the node N4 may be common to the node N1. The second current removal unit 40 determines the magnitude of the second current J2 by feeding back the first signal voltage V1.

The second current removal unit 40 in the present embodiment has a feedback circuit section 41, a smoothing capacitor 42, a second transistor 43, and a second switching element 45. The feedback circuit section 41 is connected to the signal output terminal 22 of the current-to-voltage conversion unit 20, and outputs a second signal voltage V2 having a magnitude corresponding to the first signal voltage V1. The feedback circuit section 41 in the present embodiment includes a second amplifier 44. The second amplifier 44 includes a first input terminal 44a, a second input terminal 44b, and an output terminal 44c. The first input terminal 44a is a non-inverting input terminal, and is connected to a node N5 between the signal input terminal 21 of the current-to-voltage conversion unit 20 and the photodetection element 10. The second input terminal 44b is an inverting input terminal, and is connected to the signal output terminal 22 of the current-to-voltage conversion unit 20. The output terminal 44c is connected to one electrode of the smoothing capacitor 42. The second amplifier 44 outputs the second signal voltage V2 from the output terminal 44c. The second signal voltage V2 is a voltage having a magnitude proportional to the difference between a voltage input to the first input terminal 44a and a voltage input to the second input terminal 44b, that is, the first signal voltage V1.

The smoothing capacitor 42 smooths the second signal voltage V2. The other electrode of the smoothing capacitor 42 in the present embodiment is connected to the reference potential line 62. The capacitance of the smoothing capacitor 42 is, for example, 100 fF or more and 1 pF or less. The smoothing capacitor 42 is, for example, a MOS capacitor.

The second transistor 43 is configured to extract, from the signal current J, the second current J2 having a magnitude corresponding to the second signal voltage V2 smoothed by the smoothing capacitor 42. The second transistor 43 has a control terminal 43a, a first current terminal 43b, and a second current terminal 43c. The control terminal 43a is connected to a node N6 between one electrode of the smoothing capacitor 42 and the feedback circuit section 41. The second signal voltage V2 smoothed by the smoothing capacitor 42 is applied to the control terminal 43a. The first current terminal 43b is connected to the node N4, and is connected to the photodetection element 10 through the node N4. The second current terminal 43c is connected to the reference potential line 62. The gain of the second transistor 43 is smaller than the gain of the first transistor 33, for example, 1/10 or less of the gain of the first transistor 33.

Between the node N6 and the reference potential line 62, a resistance element 421 may be provided in series with the smoothing capacitor 42, or the resistance element 421 may not be provided. In each modification described later, the resistance element 421 may be similarly provided. In the shown example, the resistance element 421 is connected between the smoothing capacitor 42 and the reference potential line 62, but the resistance element 421 may be connected between the node N6 and the smoothing capacitor 42.

The second switching element 45 is connected in series between the photodetection element 10 and the smoothing capacitor 42. The second switching element 45 is configured to switch on/off the flow of a current from the photodetection element 10 to the smoothing capacitor 42. In other words, the second switching element 45 switches the relationship between the photodetection element 10 and the smoothing capacitor 42 between a connecting state and a disconnecting state. One end of the second switching element 45 in the present embodiment is connected to a node N7 between the node N4 and the second transistor 43. The other end of the second switching element 45 in the present embodiment is connected to the node N6. The second switching element 45 in the present embodiment has a switch 45a. The switch 45a may be a mechanical switch or a semiconductor switch such as a transistor. Alternatively, the second switching element 45 may be an amplifier having a control terminal for switching whether or not to perform output. In this case, the amplifier can switch between a first state and a second state. The first state is a state in which a current (or voltage) input to the input terminal is amplified and the amplified current (or voltage) is output from the output terminal. The second state is a state in which the output terminal is in a high impedance state and a signal at the input terminal is not transferred to the output terminal.

The control unit 50 is connected to each control terminal of the first switching element 32 and the second switching element 45. The control unit 50 controls the switching operations of the first switching element 32 and the second switching element 45 individually. Specifically, the control unit 50 controls ON/OFF of the switch 32a and the switch 45a individually. Alternatively, the control unit 50 may collectively control the switching operations of the first switching element 32 and the second switching element 45, that is, ON/OFF of the switch 32a and the switch 45a. In this case, the control terminals of the first switching element 32 and the second switching element 45 may be connected to the control unit 50 through a common wiring. The control unit 50 is, for example, a timing generation circuit arranged in a chip in which the photodetection element 10, the current-to-voltage conversion unit 20, the first current removal unit 30, and the second current removal unit 40 are mounted. Alternatively, the control unit 50 may be, for example, a personal computer, a smart device such as a smartphone or a tablet terminal, or a computer such as a cloud server. A computer as the control unit 50 includes an HDD (Hard Disk Drive), a storage device such as a flash memory or a RAM (Random Access Memory), and a processor (CPU: Central Processing Unit). The control unit 50 may be a microcomputer or an FPGA (Field-Programmable Gate Array).

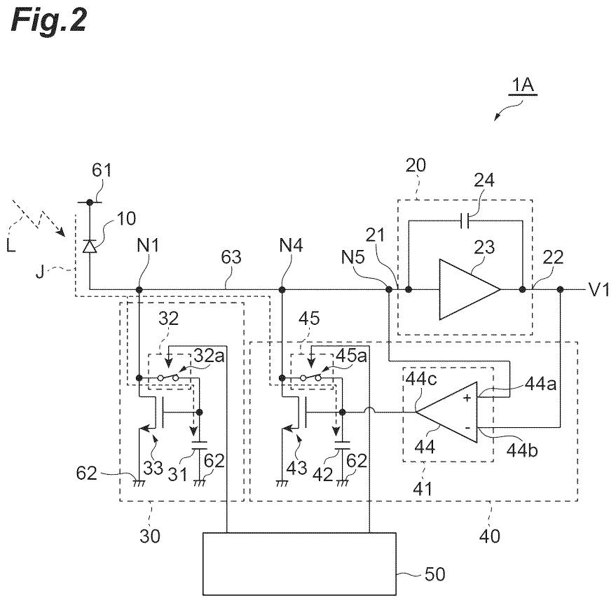

The photodetection circuit 1A according to the present embodiment having the above configuration operates as follows. First, in a period during which the first signal voltage V1 output from the photodetection circuit 1A is not used outside the photodetection circuit 1A, the control unit 50 controls the first switching element 32 so that the current flows from the photodetection element 10 to the voltage-holding capacitor 31. As shown in FIG. 2, the first switching element 32 allows a part of the signal current J to flow from the photodetection element 10 to the voltage-holding capacitor 31. As a result, charge is accumulated in the voltage-holding capacitor 31 to increase the voltage across the voltage-holding capacitor 31. At this time, the voltage-holding capacitor 31 allows a high frequency signal component contained in the signal current J to pass therethrough. Therefore, the voltage across the voltage-holding capacitor 31 depends mainly on the magnitude of the low-frequency component contained in the signal current J.

In the above period, the control unit 50 controls the second switching element 45 so that the current flows from the photodetection element 10 to the smoothing capacitor 42. As shown in FIG. 2, the second switching element 45 allows the remainder of the signal current J to flow from the photodetection element 10 to the smoothing capacitor 42. As a result, charge is accumulated in the smoothing capacitor 42, and the voltage across the smoothing capacitor 42 increases. At this time, the smoothing capacitor 42 allows the high frequency signal component contained in the signal current J to pass therethrough. Therefore, the voltage across the smoothing capacitor 42 depends mainly on the magnitude of the low-frequency component contained in the signal current J.

The period during which the signal current J flows from the photodetection element 10 to the voltage-holding capacitor 31 and the period during which the signal current J flows from the photodetection element 10 to the smoothing capacitor 42 may or may not overlap.

As the accumulation of charge in the voltage-holding capacitor 31 and the smoothing capacitor 42 progresses, the voltage across the voltage-holding capacitor 31 and the voltage across the smoothing capacitor 42 gradually stop changing. The first signal voltage V1 output from the photodetection circuit 1A is used outside the photodetection circuit 1A after the switching timing, which is the timing when the voltage across the voltage-holding capacitor 31 and the voltage across the smoothing capacitor 42 hardly change.

At the switching timing, the control unit 50 switches the first switching element 32 so that no current flows from the photodetection element 10 to the voltage-holding capacitor 31. As a result, the voltage across the voltage-holding capacitor 31 is determined based on the magnitude of the low-frequency component at the switching timing, and is maintained at a constant value even after the switching timing. The voltage across the voltage-holding capacitor 31 is applied to the control terminal 33a of the first transistor 33. As a result, as shown in FIG. 1, the first transistor 33 extracts the first current J1 having a magnitude corresponding to the voltage across the voltage-holding capacitor 31 from the signal current J. The control unit 50 maintains the state of the first switching element 32 so that no current flows from the photodetection element 10 to the voltage-holding capacitor 31 while the first signal voltage V1 is used outside the photodetection circuit 1A.

At the switching timing or another timing, the control unit 50 switches the second switching element 45 so that no current flows from the photodetection element 10 to the smoothing capacitor 42. Therefore, the smoothing capacitor 42 can perform the operation of smoothing the second signal voltage V2. As shown in FIG. 1, the second transistor 43 extracts the second current J2 having a magnitude corresponding to the smoothed second signal voltage V2 from the signal current J. The control unit 50 maintains the state of the second switching element 45 so that no current flows from the photodetection element 10 to the smoothing capacitor 42 while the first signal voltage V1 is used outside the photodetection circuit 1A.

The effects obtained by the photodetection circuit 1A according to the present embodiment described above will be described. According to the photodetection circuit 1A according to the present embodiment, a certain portion of the low-frequency component contained in the signal current J, that is, the first current J1, is extracted from the signal current J by the first current removal unit 30. The remaining portion of the low-frequency component contained in the signal current J, that is, the second current J2, is extracted from the signal current J by the second current removal unit 40. The second current J2 is a fluctuation of the low-frequency component after the switching timing at which the first switching element 32 is switched. With this configuration, a low-frequency component to be removed by the second current removal unit 40 that performs a feedback operation of the low-frequency component is reduced, compared to a case where the first current removal unit 30 is not provided. Therefore, the transconductance of the second transistor 43 decreases, and the loop gain decreases. As a result, the frequency band of the low-frequency component extracted from the signal current J in the second current removal unit 40, that is, the frequency band of the second current J2, becomes narrow. In addition, since the charge to be accumulated in the smoothing capacitor 42 is reduced, the time required to accumulate the charge in the smoothing capacitor 42 is shortened. Therefore, the settling time of the feedback operation can be shortened. Thus, according to the photodetection circuit 1A according to the present embodiment, it is possible to shorten the settling time of the feedback operation while keeping the frequency band of the low-frequency component extracted from the signal current J small.

Most of the photodetection elements that generate a large dark current have a central sensitivity in the near infrared to mid-infrared wavelength range. Therefore, when a photodetection element having a central sensitivity in the near-infrared to mid-infrared wavelength band is used as the photodetection element 10 in the present embodiment, the above-described effects become even more noticeable. In addition, most of the photodetection elements that generate a large dark current are compound semiconductors. Therefore, when a photodetection element containing a compound semiconductor as a semiconductor material is used as the photodetection element 10 in the present embodiment, the above-described effects become even more noticeable. Representative examples of a semiconductor material used in photodetection elements that generate a large dark current include Ge, InGaAs, and InAsSb. The central sensitivity of a photodetection element using Ge is 1.6 um or less. The central sensitivity of a photodetection element using InGaAs is 2.6 μm or less. The central sensitivity of a photodetection element using InAsSb is 12 μm or less. A photodetection element containing any of these semiconductor materials is mainly used in the near infrared to mid-infrared wavelength range. The above-described effects become even more noticeable even when a photodetection element containing any of these semiconductor materials is used.

As in the present embodiment, the first current removal unit 30 may include the voltage-holding capacitor 31, the first switching element 32, and the first transistor 33. The voltage-holding capacitor 31 is configured to be charged by the current from the photodetection element 10. The first switching element 32 is configured to switch on/off the flow of a current from the photodetection element 10 to the voltage-holding capacitor 31. The first transistor 33 has the control terminal 33a, the first current terminal 33b, and the second current terminal 33c. A voltage based on the voltage across the voltage-holding capacitor 31 is applied to the control terminal 33a. The first current terminal 33b is connected to the photodetection element 10. The second current terminal 33c is connected to the reference potential line 62. Since the first current removal unit 30 has such a configuration, for example, the magnitude of the first current J1 can be determined based on the magnitude of the low-frequency component at a predetermined timing, that is, the switching timing.

As in the present embodiment, the second current removal unit 40 may include the second switching element 45. The second switching element 45 is connected in series between the photodetection element 10 and the smoothing capacitor 42, and switches on/off the flow of a current from the photodetection element 10 to the smoothing capacitor 42. In this case, the charge can be accumulated in advance in the smoothing capacitor 42 before the first signal voltage V1 is used outside the photodetection circuit 1A. Therefore, the settling time of the feedback operation in the second current removal unit 40 can be further shortened.

As in the present embodiment, the resistance element 421 may be provided in series with the smoothing capacitor 42 between the node N6 and the reference potential line 62. In this case, the phase lag at high frequencies can be reduced by the resistance element 421. Therefore, the stability of the feedback operation of the second current removal unit 40 can be improved.

### First Modification

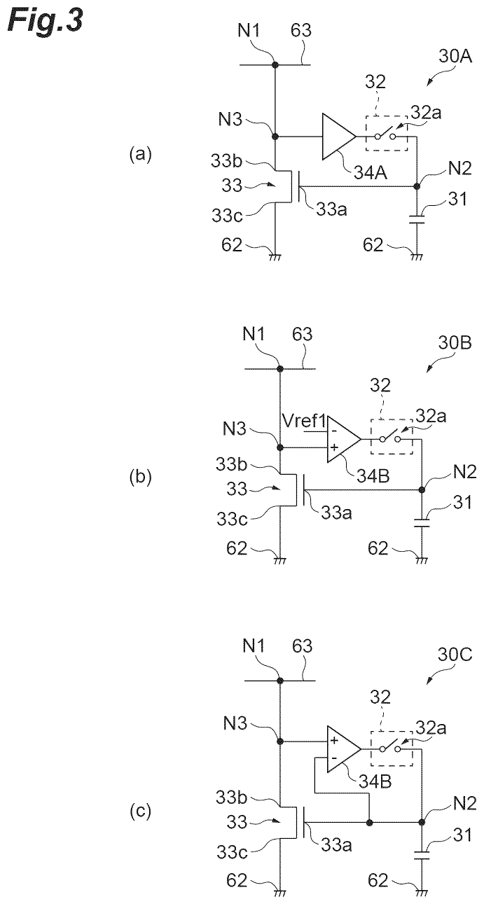

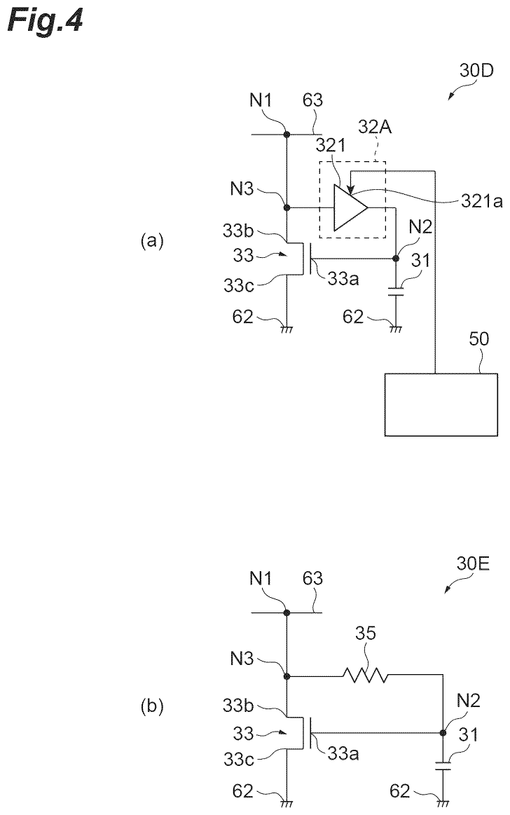

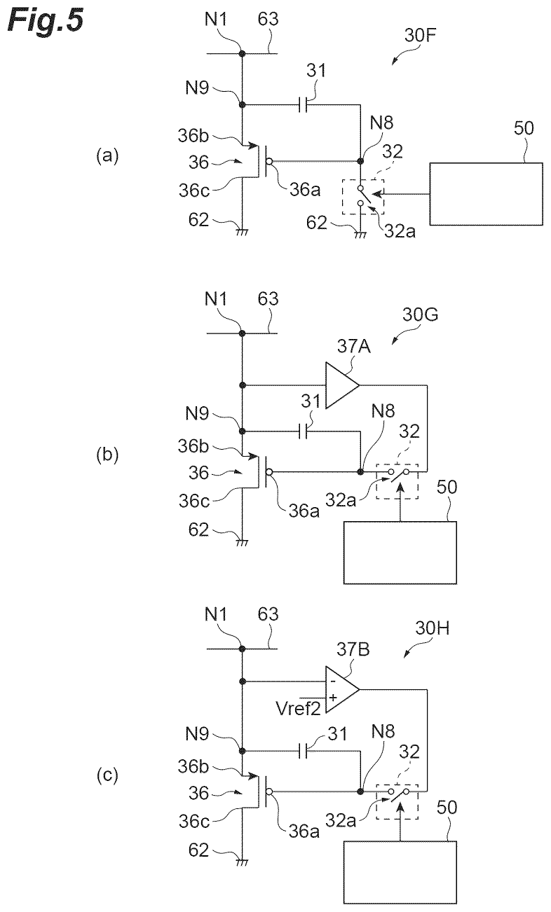

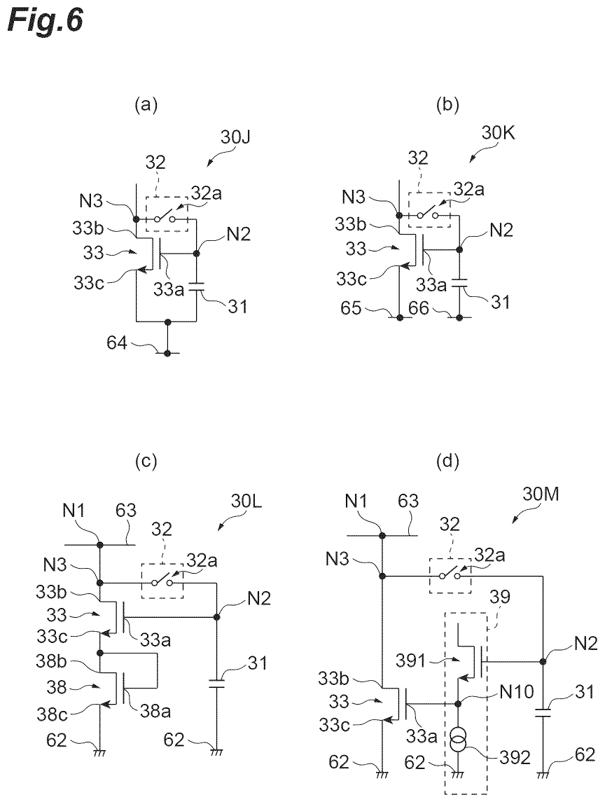

(a) to (c) in FIG. 3, (a) and (b) in FIG. 4, (a) to (c) in FIG. 5, and (a) to (d) in FIG. 6 are circuit diagrams showing the configurations of first current removal units 30A to 30M according to a modification of the above embodiment. The photodetection circuit 1A according to the above embodiment may include any one of the first current removal units 30A to 30M instead of the first current removal unit 30.

The first current removal unit 30A shown in (a) in FIG. 3 further includes a first amplifier 34A in addition to the configuration of the first current removal unit 30 in the above embodiment. The first amplifier 34A is configured to amplify the current flowing from the photodetection element 10 to the voltage-holding capacitor 31. Alternatively, the first amplifier 34A may be configured to amplify the voltage applied from the photodetection element 10 to the voltage-holding capacitor 31. Specifically, the first amplifier 34A is connected in series with the first switching element 32 between the node N3 and the node N2. In the shown example, the first amplifier 34A is connected between the node N3 and the first switching element 32, but the first amplifier 34A may be connected between the first switching element 32 and the node N2. In this case, the first amplifier 34A may have a control terminal for selecting whether or not to perform output. By setting the output terminal of the first amplifier 34A to have a high impedance state, it is possible to prevent leakage of charge through the first amplifier 34A. The input terminal of the first amplifier 34A is connected to the photodetection element 10 through the node N3 and the node N1. The output terminal of the first amplifier 34A is connected to the voltage-holding capacitor 31 through the node N2. According to the first current removal unit 30A, since the charge due to the signal current J can be accumulated in the voltage-holding capacitor 31 more quickly, the time required for charge accumulation can be shortened. In the above embodiment, the time required for the charge to accumulate in the voltage-holding capacitor 31 is the time during which the first signal voltage V1 corresponding to the light intensity of the signal light L cannot be output, that is, the dead time. According to the first current removal unit 30A, it is possible to shorten the dead time.

As shown in (b) in FIG. 3, the first current removal unit 30B has a first amplifier 34B instead of the first amplifier 34A of the first current removal unit 30A. The first amplifier 34B is also configured to amplify the current flowing from the photodetection element 10 to the voltage-holding capacitor 31 or the voltage applied from the photodetection element 10 to the voltage-holding capacitor 31. The first amplifier 34B has an inverting input terminal and a non-inverting input terminal, and the non-inverting input terminal is connected to the node N3. A predetermined reference voltage Vref1 is input to the inverting input terminal of the first amplifier 34B. Alternatively, as in the first current removal unit 30C shown in (c) in FIG. 3, the inverting input terminal of the first amplifier 34B may be connected to the node N2. These first current removal units 30B and 30C can also achieve the same effects as the first current removal unit 30A described above. In addition, according to the first current removal unit 30B, the voltage at the node N3 can be set to an arbitrary reference voltage regardless of the magnitude of the current input to the first current removal unit 30B. Therefore, the error in the magnitude of the first current J1 caused by the channel length modulation effect of the first transistor 33 can be reduced.

The first current removal unit 30D shown in (a) in FIG. 4 has a first switching element 32A instead of the first switching element 32 of the first current removal unit 30 in the above embodiment. The first switching element 32A includes an amplifier 321, and is configured to amplify the current flowing from the photodetection element 10 to the voltage-holding capacitor 31 or the voltage applied from the photodetection element 10 to the voltage-holding capacitor 31. The first switching element 32A has a control terminal 321a for selecting whether or not to perform output. The first switching element 32A can switch between a first state and a second state. The first state is a state in which a current (or voltage) input to the input terminal is amplified and the amplified current (or voltage) is output from the output terminal. The second state is a state in which the output terminal is in a high impedance state and a signal at the input terminal is not transferred to the output terminal. The control terminal of the amplifier 321 for switching is connected to the control unit 50. The control unit 50 controls the switching operation of the first switching element 32A in the same manner as the first switching element 32 in the above embodiment. As in this modification, the first switching element may have a function of amplifying a current (or voltage).

The first current removal unit 30E shown in (b) in FIG. 4 has a first resistance element 35 instead of the first switching element 32 of the first current removal unit 30 in the above embodiment. The first resistance element 35 is provided on the path of a current flowing from the photodetection element 10 to the voltage-holding capacitor 31. Specifically, one end of the first resistance element 35 is connected to the photodetection element 10 through the node N3 and the node N1. The other end of the first resistance element 35 is connected to one electrode of the voltage-holding capacitor 31 through the node N2. The resistance value of the first resistance element 35 is relatively high, for example, 100 kΩ or more and 10 MΩ or less.

When the photodetection circuit 1A includes the first current removal unit 30E, the photodetection circuit 1A operates, for example, as follows. First, in a period during which the first signal voltage V1 (see FIG. 1) output from the photodetection circuit 1A is not used outside the photodetection circuit 1A, a part of the signal current J flows from the photodetection element 10 to the voltage-holding capacitor 31 through the first resistance element 35. As a result, charge is accumulated in the voltage-holding capacitor 31 to increase the voltage across the voltage-holding capacitor 31. The first signal voltage V1 output from the photodetection circuit 1A is used outside the photodetection circuit 1A after the timing at which the voltage across the voltage-holding capacitor 31 hardly changes. If the period during which the first signal voltage V1 is used is sufficiently short, the voltage across the voltage-holding capacitor 31 is determined based on the magnitude of the low-frequency component at that timing and is maintained at an approximately constant value during that period. The voltage across the voltage-holding capacitor 31 is applied to the control terminal 33a of the first transistor 33. As a result, the first transistor 33 extracts, from the signal current J, the first current J1 (see FIG. 1) having a magnitude corresponding to the voltage across the voltage-holding capacitor 31. In this manner, also in this modification, the magnitude of the first current J1 can be determined based on the magnitude of the low-frequency component at a predetermined timing.

As shown in (a) in FIG. 4, the first switching element 32A may include the amplifier 321 having the control terminal 321a for selecting whether or not to perform output. In this case, the charge due to the signal current J can be accumulated in the voltage-holding capacitor 31 more quickly. Therefore, the time required for charge accumulation can be shortened. The time required for the charge to accumulate in the voltage-holding capacitor 31 is the time during which the first signal voltage V1 corresponding to the light intensity of the signal light L cannot be output, that is, the dead time. According to the first current removal unit 30D shown in (a) in FIG. 4, it is possible to shorten the dead time. In addition, by providing the amplifier 321 with a function of switching on/off the flow of a current from the photodetection element 10 to the voltage-holding capacitor 31, the number of components can be further reduced compared to the case where an amplifier is provided separately from the first switching element 32.

The first current removal units 30F to 30H shown in (a) to (c) in FIG. 5 have a first transistor 36 instead of the first transistor 33 in the above embodiment. The first transistor 36 in this modification is a P-channel MOSFET. The first transistor 36 is configured to extract, from the signal current J, the first current J1 having a magnitude corresponding to the voltage across the voltage-holding capacitor 31. The first transistor 36 has a control terminal 36a (gate), a first current terminal 36b (source), and a second current terminal 36c (drain).

In the first current removal unit 30F shown in (a) in FIG. 5, one electrode of the voltage-holding capacitor 31 is connected to the node N1 between the photodetection element 10 and the first transistor 36. The other electrode of the voltage-holding capacitor 31 is connected to one end of the first switching element 32. The other end of the first switching element 32 is connected to the reference potential line 62. In this manner, the first switching element 32 is connected in series between the voltage-holding capacitor 31 and the reference potential line 62. As in the above embodiment, the first switching element 32 switches on/off the flow of a current from the photodetection element 10 to the voltage-holding capacitor 31.

The control terminal 36a of the first transistor 36 is connected to the node N8 between the other electrode of the voltage-holding capacitor 31 and the first switching element 32. A voltage based on the voltage across the voltage-holding capacitor 31, for example, the voltage across the voltage-holding capacitor 31 itself, is applied to the control terminal 36a. The first current terminal 36b is connected to a node N9 between the voltage-holding capacitor 31 and the node N1, and is connected to the photodetection element 10 through the nodes N9 and N1. The second current terminal 36c is connected to the reference potential line 62. The photodetection circuit 1A including the first current removal unit 30F shown in (a) in FIG. 5 can achieve the same effects as in the above embodiment.

The first current removal unit 30G shown in (b) in FIG. 5 further includes a first amplifier 37A in addition to the configuration of the first current removal unit 30F shown in (a) in FIG. 5. The first amplifier 37A is configured to amplify the current flowing from the photodetection element 10 to the voltage-holding capacitor 31 or the voltage applied from the photodetection element 10 to the voltage-holding capacitor 31. Specifically, the first amplifier 37A is connected in series with the first switching element 32 between the nodes N9 and N8. In this embodiment, the other end of the first switching element 32 is connected to the output terminal of the first amplifier 37A instead of the reference potential line 62. In the shown example, the first amplifier 37A is connected between the node N9 and the first switching element 32, but the first amplifier 37A may be connected between the first switching element 32 and the node N8. In this case, the first amplifier 37A may have a control terminal for selecting whether or not to perform output, like the first switching element 32A shown in (a) in FIG. 4. By setting the output terminal of the first amplifier 37A to have a high impedance state, it is possible to prevent leakage of charge through the first amplifier 37A. The input terminal of the first amplifier 37A is connected to the photodetection element 10 through the node N1. According to the first current removal unit 30G, the charge due to the signal current J can be accumulated in the voltage-holding capacitor 31 more quickly. Therefore, the time required for charge accumulation can be shortened. The time required for the charge to accumulate in the voltage-holding capacitor 31 is the time during which the first signal voltage V1 corresponding to the light intensity of the signal light L cannot be output, that is, the dead time. According to the first current removal unit 30G, it is possible to shorten the dead time.

The first current removal unit 30H shown in (c) in FIG. 5 has a first amplifier 37B instead of the first amplifier 37A of the first current removal unit 30G. The first amplifier 37B is also configured to amplify the current flowing from the photodetection element 10 to the voltage-holding capacitor 31 or the voltage applied from the photodetection element 10 to the voltage-holding capacitor 31. The first amplifier 37B has an inverting input terminal and a non-inverting input terminal, and the inverting input terminal is connected to the node N1 and the node N9. A predetermined reference voltage Vref2 is input to the non-inverting input terminal of the first amplifier 37B. The first current removal unit 30H can also achieve the same effects as the first current removal unit 30G described above. In addition, the voltage at the node N9 can be set to an arbitrary reference voltage regardless of the magnitude of the current input to first current removal unit 30H. Therefore, the error in the magnitude of the first current J1 caused by the channel length modulation effect of the first transistor 36 can be reduced.

In the first current removal unit 30J shown in (a) in FIG. 6, both the second current terminal 33c of the first transistor 33 and the other electrode of the voltage-holding capacitor 31 are connected to a common third constant potential line 64 having a different potential from the reference potential line 62. The potential of the third constant potential line 64 is lower than the potential of the bias line 61. In a first current removal unit 30K shown in (b) in FIG. 6, the second current terminal 33c of the first transistor 33 is connected to a fourth constant potential line 65 having a different potential from the reference potential line 62. The other electrode of the voltage-holding capacitor 31 is connected to a fifth constant potential line 66 having a different potential from the reference potential line 62 and the fourth constant potential line 65. The photodetection circuit 1A including either the first current removal unit 30J or 30K can achieve the same effect as in the above embodiment.

The first current removal unit 30L shown in (c) in FIG. 6 further includes a transistor 38 in addition to the configuration of the first current removal unit 30 in the above embodiment. The transistor 38 is connected in series with the first transistor 33 between the photodetection element 10 and the reference potential line 62. The transistor 38 has a control terminal 38a, a first current terminal 38b, and a second current terminal 38c. The first current terminal 38b is connected to the second current terminal 33c of the first transistor 33. The second current terminal 38c is connected to the reference potential line 62. A voltage based on the voltage across the voltage-holding capacitor 31 is applied to the control terminal 38a. In the shown example, the control terminal 38a is shorted to the first current terminal 38b, and the voltage of the second current terminal 33c of the first transistor 33 is applied to the control terminal 38a.

As in this modification, by connecting the transistor 38 in series with the first transistor 33, it is possible to adjust the magnitude of the gate voltage required to turn on the first transistor 33. That is, by connecting the transistor 38 between the first transistor 33 and the reference potential line 62 as in the shown example, the gate voltage required to turn on the first transistor 33 can be increased by the gate-source voltage of the transistor 38. Similarly, in the second current removal unit 40, another transistor may be connected in series with the second transistor 43. In this case, for example, when the output voltage range of the second amplifier 44 is limited, the magnitude of the gate voltage required to turn on the second transistor 43 can be adjusted to match the output voltage range of the second amplifier 44.

The first current removal unit 30M shown in (d) in FIG. 6 further includes a source follower circuit 39 in addition to the configuration of the first current removal unit 30 in the above embodiment. The source follower circuit 39 includes a transistor 391 and a current source 392. The transistor 391 is, for example, a FET. The gate of the transistor 391 is connected to the node N2, and the source of the transistor 391 is connected to the reference potential line 62 through the current source 392. The control terminal 33a of the first transistor 33 is connected to a node N10 between the transistor 391 and the current source 392, and is connected to the node N2 through the transistor 391.

In this modification, the magnitude of the voltage across the voltage-holding capacitor 31 required to turn on the first transistor 33 can be adjusted. That is, by connecting the source follower circuit 39 between the first transistor 33 and one electrode of the voltage-holding capacitor 31 as in the shown example, the voltage across the voltage-holding capacitor 31 required to turn on the first transistor 33 can be increased by the gate-source voltage of the transistor 391. When the source follower circuit 39 is provided, the first transistor 33 may be a bipolar transistor.

### Second Modification

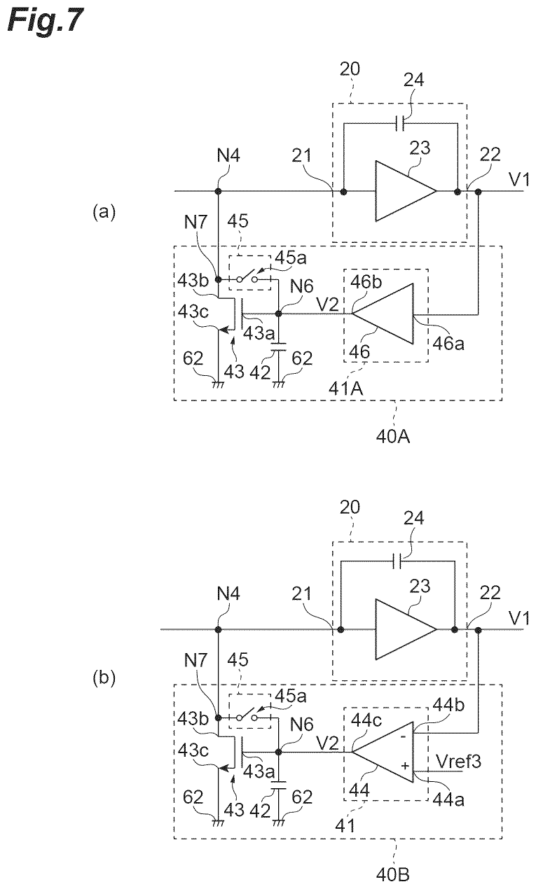

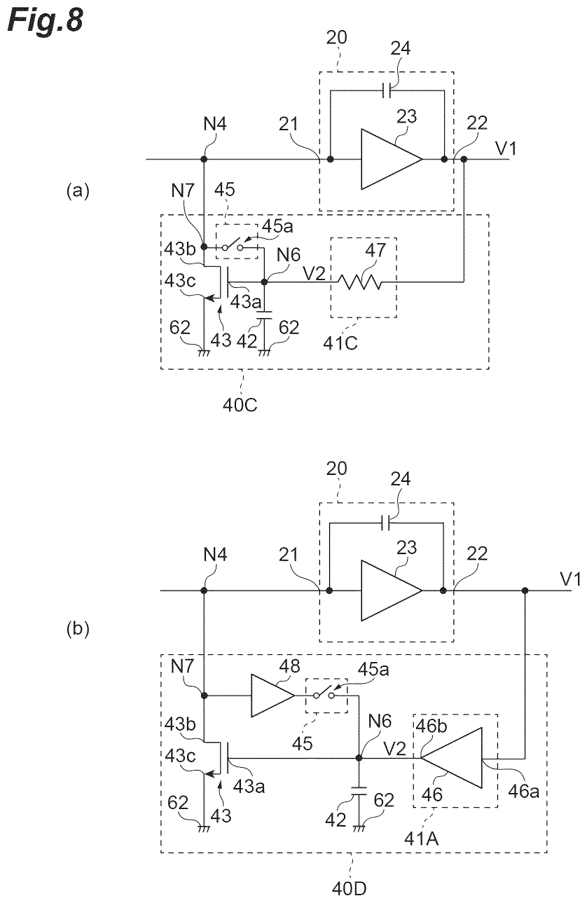

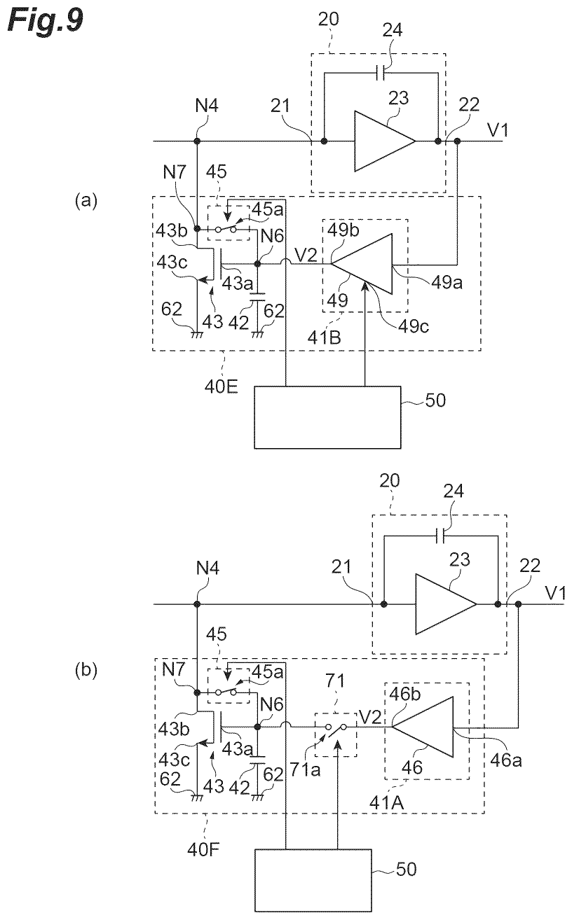

(a) and (b) in FIG. 7, (a) and (b) in FIG. 8, and (a) and (b) in FIG. 9 are circuit diagrams showing the configurations of second current removal units 40A to 40F according to a modification of the above embodiment. The photodetection circuit 1A according to the above embodiment may include any one of the second current removal units 40A to 40F instead of the second current removal unit 40.

The second current removal unit 40A shown in (a) in FIG. 7 has a feedback circuit section 41A instead of the feedback circuit section 41 in the above embodiment. The configuration other than the feedback circuit section 41A is the same as that of the second current removal unit 40 in the above embodiment. The feedback circuit section 41A in this modification includes a second amplifier 46. The second amplifier 46 includes an input terminal 46a and an output terminal 46b. The input terminal 46 a is connected to the signal output terminal 22 of the current-to-voltage conversion unit 20. The output terminal 46b is connected to one electrode of the smoothing capacitor 42 through the node N6. The second amplifier 46 outputs, from the output terminal 46b, the second signal voltage V2 having a magnitude proportional to the voltage input to the input terminal 46a. As in this modification, an amplifier forming the feedback circuit section may have a single input terminal.

The second current removal unit 40B shown in (b) in FIG. 7 has the same configuration as the second current removal unit 40 in the above embodiment, except for the following points. That is, in the second current removal unit 40B, the first input terminal 44a of the second amplifier 44 in the feedback circuit section 41 is not connected to the node N5 shown in FIG. 1, but receives a reference voltage Vref3. According to the second current removal unit 40B, it is possible to achieve the same effects as those of the second current removal unit 40 described above.

The second current removal unit 40C shown in (a) in FIG. 8 has a feedback circuit section 41C instead of the feedback circuit section 41 in the above embodiment. The configuration other than the feedback circuit section 41C is the same as that of the second current removal unit 40 in the above embodiment. The feedback circuit section 41C in this modification includes a second resistance element 47. One end of the second resistance element 47 is connected to the signal output terminal 22 of the current-to-voltage conversion unit 20. The other end of the second resistance element 47 is connected to one electrode of the smoothing capacitor 42 through the node N6. The resistance value of the second resistance element 47 is, for example, 100 kΩ or more and 10 MΩ or less. The feedback circuit section 41C outputs the second signal voltage V2 having a magnitude corresponding to the first signal voltage V1. According to the second current removal unit 40C, it is possible to achieve the same effects as those of the second current removal unit 40 described above.

The second current removal unit 40D shown in (b) in FIG. 8 further includes a third amplifier 48 in addition to the configuration of the second current removal unit 40A shown in (a) in FIG. 7. The third amplifier 48 is configured to amplify the current flowing from the photodetection element 10 to the smoothing capacitor 42 or the voltage applied from the photodetection element 10 to the smoothing capacitor 42. In this modification, the third amplifier 48 is connected in series with the second switching element 45 between the nodes N7 and N6. In the shown example, the third amplifier 48 is connected in series between the node N7 and the second switching element 45, but the third amplifier 48 may be connected between the second switching element 45 and the node N6. In this case, the third amplifier 48 may have a control terminal for selecting whether or not to perform output. By setting the output terminal of the third amplifier 48 to a high impedance state, it is possible to prevent leakage of charge through the third amplifier 48. According to this modification, charge can be accumulated in the smoothing capacitor 42 more quickly. Therefore, the time required for charge accumulation can be shortened. The time required for the charge to accumulate in the smoothing capacitor 42 is the time during which the first signal voltage V1 corresponding to the light intensity of the signal light L cannot be output, that is, the dead time. According to the second current removal unit 40D, it is possible to shorten the dead time. The second current removal unit 40D may have the second resistance element 47 (see (a) in FIG. 8) instead of the second amplifier 46.

The third amplifier 48 may have an inverting input terminal and a non-inverting input terminal. In this case, the non-inverting input terminal is connected to the node N7, and a predetermined reference voltage is input to the inverting input terminal. Then, the voltage at the node N7 can be set to an arbitrary reference voltage regardless of the magnitude of the current input to the second current removal unit 40D. Therefore, the error in the magnitude of the second current J2 caused by the channel length modulation effect of the second transistor 43 can be reduced. Alternatively, the inverting input terminal may be connected to the node N6.

Alternatively, instead of the second switching element 45 and the third amplifier 48, a second switching element including an amplifier may be provided. In this case, the amplifier of the second switching element is configured to amplify the current flowing from the photodetection element 10 to the smoothing capacitor 42 or the voltage applied from the photodetection element 10 to the smoothing capacitor 42. In addition, the amplifier has a control terminal for selecting whether or not to perform output. The amplifier can switch between a first state and a second state. The first state is a state in which a current (or voltage) input to the input terminal is amplified and the amplified current (or voltage) is output from the output terminal. The second state is a state in which the output terminal is in a high impedance state and a signal at the input terminal is not transferred to the output terminal. The control terminal of the amplifier for switching is connected to the control unit 50. The control unit 50 controls the switching operation of the amplifier in the same manner as the second switching element 45 in the above embodiment. As described above, the second switching element may have a function of amplifying the current (or voltage).

The second current removal unit 40E shown in (a) in FIG. 9 has a feedback circuit section 41B instead of the feedback circuit section 41 in the above embodiment. The configuration other than the feedback circuit section 41B is the same as that of the second current removal unit 40 in the above embodiment. The feedback circuit section 41B includes a second amplifier 49. The second amplifier 49 includes an input terminal 49a, an output terminal 49b, and a control terminal 49c. The input terminal 49a is connected to the signal output terminal 22 of the current-to-voltage conversion unit 20. The output terminal 49b is connected to one electrode of the smoothing capacitor 42 through the node N6. The second amplifier 49 outputs, from the output terminal 49b, the second signal voltage V2 having a magnitude proportional to the voltage input to the input terminal 49a. The control terminal 49c is a terminal for selecting whether or not to output the output voltage, that is, the second signal voltage V2. The second amplifier 49 is in either a first state or a second state in response to a control signal input to the control terminal 49c. The first state is a state in which the second signal voltage V2 is output. The second state is a state in which the output terminal 49b is in a high impedance state and a signal at the input terminal 49a is not transferred to the output terminal 49b. The control terminal 49c is connected to the control unit 50, and a control signal is input from the control unit 50 to the control terminal 49c. According to this modification, when accumulating the charge in advance in the smoothing capacitor 42, the second amplifier 49 can be controlled so as not to output the output voltage, that is, the second signal voltage V2. Thus, this prevents a part of the current from the photodetection element 10 from flowing into the second amplifier 49, the charge can be efficiently accumulated in the smoothing capacitor 42. Although the case where the second amplifier has a single input terminal has been exemplified in the above description, the second amplifier may have a differential input, that is, an inverting input terminal and a non-inverting input terminal.

The second amplifier 49 may be a transconductance amplifier that outputs, from the output terminal 49b, a current having a magnitude proportional to the voltage input to the input terminal 49a. In this case, the control terminal 49c is a terminal for selecting whether or not to output a current. The second amplifier 49 is in either a first state or a second state in response to a control signal input to the control terminal 49c. The first state is a state in which a current having a magnitude proportional to the input voltage is output. The second state is a state in which the output terminal 49b is in a high impedance state and a signal at the input terminal 49a is not transferred to the output terminal 49b. In this case as well, when accumulating the charge in advance in the smoothing capacitor 42, the second amplifier 49 can be controlled so as not to output a current. Thus, this prevents a part of the current from the photodetection element 10 from flowing into the second amplifier 49, the charge can be efficiently accumulated in the smoothing capacitor 42.

The second current removal unit 40F shown in (b) in FIG. 9 further includes a third switching element 71 in addition to the configuration of the second current removal unit 40A shown in (a) in FIG. 7. The third switching element 71 is connected in series between the second amplifier 46 and the smoothing capacitor 42. The third switching element 71 switches the relationship between the second amplifier 46 and the smoothing capacitor 42 between a connecting state and a disconnecting state. In one example, the third switching element 71 includes a switch 71a. The switch 71a may be a mechanical switch or a semiconductor switch such as a transistor. The switching operation of the third switching element 71 is controlled by the control unit 50. According to this modification, when accumulating the charge in advance in the smoothing capacitor 42, the third switching element 71 can be made to have a disconnecting state. Thus, this prevents a part of the current from the photodetection element 10 from flowing into the second amplifier 46, the charge can be efficiently accumulated in the smoothing capacitor 42. Although the case where the second amplifier has a single input terminal has been exemplified in the above description, the second amplifier may have a differential input, that is, an inverting input terminal and a non-inverting input terminal.

### Third Modification

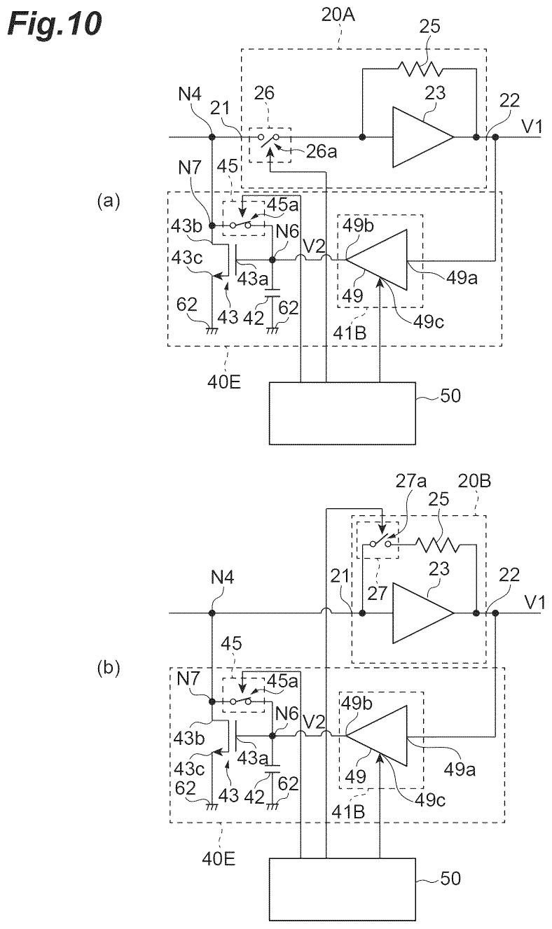

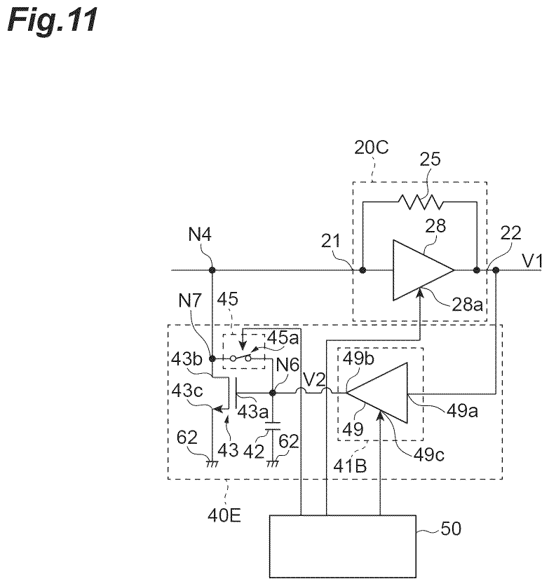

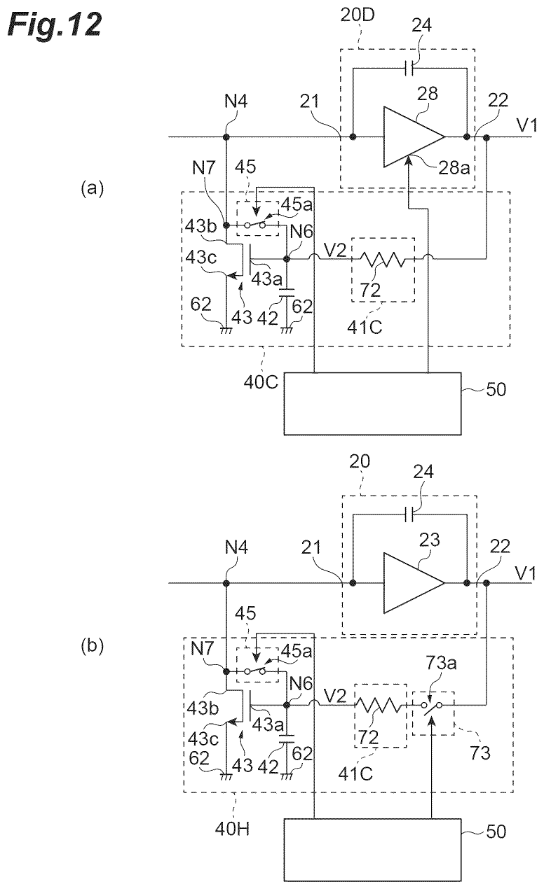

(a) and (b) in FIG. 10, FIG. 11, and (a) in FIG. 12 are circuit diagrams respectively showing the configurations of current-to-voltage conversion units 20A to 20D according to a modification of the above-described embodiment. The photodetection circuit 1A according to the above embodiment may include any one of the current-to-voltage conversion units 20A to 20D instead of the current-to-voltage conversion unit 20. Each of the current-to-voltage conversion units 20A to 20D is configured to be able to switch on/off the input of the signal current J to the signal input terminal 21.

Each of the current-to-voltage conversion units 20A and 20B shown in (a) and (b) in FIG. 10 has a resistor 25 instead of the capacitor 24 in the above embodiment. That is, the current-to-voltage conversion units 20A and 20B are transimpedance amplifiers. One end of the resistor 25 is connected to the input terminal of the amplifier 23, and the other end of the resistor 25 is connected to the output terminal of the amplifier 23. The current-to-voltage conversion unit 20A has a fourth switching element 26, and the current-to-voltage conversion unit 20B has a fourth switching element 27. The fourth switching element 26 of the current-to-voltage conversion unit 20A is connected in series between the node N4 and both the amplifier 23 and the resistor 25. The fourth switching element 26 switches the relationship between the node N4 and both the amplifier 23 and the resistor 25 between a connecting state and a disconnecting state. The fourth switching element 27 of the current-to-voltage conversion unit 20B is connected in series with the resistor 25 between the input terminal and the output terminal of the amplifier 23. In the shown example, the fourth switching element 27 is connected between the input terminal of the amplifier 23 and the resistor 25, but the fourth switching element 27 may be connected between the resistor 25 and the output terminal of the amplifier 23. The fourth switching element 27 switches the relationship between the input terminal and the output terminal of the amplifier 23 between a connecting state and a disconnecting state. The fourth switching elements 26 and 27 in this modification have switches 26a and 27a, respectively. The switches 26a and 27a may be mechanical switches or semiconductor switches such as transistors.

According to these current-to-voltage conversion units 20A and 20B, when accumulating the charge in advance in the smoothing capacitor 42, the fourth switching elements 26 and 27 are made to have a disconnecting state so that the signal current J is not input to the signal input terminal 21. Thus, this prevents a part of the current from the photodetection element 10 from flowing out to the current-to-voltage conversion unit, the charge can be efficiently accumulated in the smoothing capacitor 42.

The current-to-voltage conversion unit 20C shown in FIG. 11 has a resistor 25 instead of the capacitor 24 in the above embodiment. That is, the current-to-voltage conversion unit 20C is a transimpedance amplifier. In addition, the current-to-voltage conversion unit 20C has an amplifier 28 instead of the amplifier 23. The amplifier 28 has a control terminal 28a in addition to an input terminal and an output terminal. The control terminal 28a is a terminal for receiving a control signal for selecting whether or not the output terminal is to be set to have a high impedance state. The amplifier 28 is in either a first state or a second state in response to a control signal input to the control terminal 28a. The first state is a state in which the first signal voltage V1 is output. The second state is a state in which the output terminal is in a high impedance state and a signal at the input terminal is not transferred to the output terminal. The control terminal 28a is connected to the control unit 50, and a control signal is input from the control unit 50 to the control terminal 28a.

According to the current-to-voltage conversion unit 20C, when accumulating the charge in advance in the smoothing capacitor 42, the output terminal of the amplifier 28 can be made to have a high impedance state. As a result, the signal current J is not input to the signal input terminal 21. Therefore, since a part of the current from the photodetection element 10 is prevented from flowing out to the current-to-voltage conversion unit, the charge can be efficiently accumulated in the smoothing capacitor 42.

The current-to-voltage conversion unit 20D shown in (a) in FIG. 12 is a charge amplifier having a capacitor 24, and has an amplifier 28 instead of the amplifier 23. The configuration of the amplifier 28 is similar to that of the current-to-voltage conversion unit 20C shown in FIG. 11. This current-to-voltage conversion unit 20D is used in combination with the second current removal unit 40C shown in (a) in FIG. 8, that is, a second current removal unit having a resistance element as a feedback circuit section. The current-to-voltage conversion unit 20D can also achieve the same effects as the current-to-voltage conversion unit 20C.

### Fourth Modification

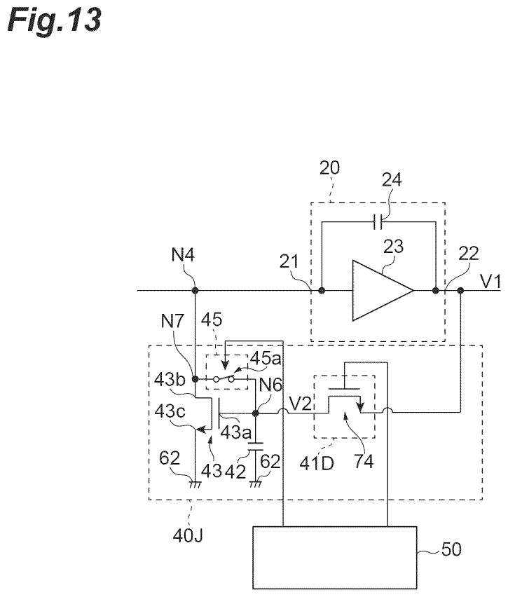

(b) in FIG. 12 and FIG. 13 are circuit diagrams respectively showing the configurations of second current removal units 40H and 40J according to a modification of the above embodiment. The photodetection circuit 1A according to the above embodiment may include any one of the second current removal units 40H and 40J instead of the second current removal unit 40.

The second current removal unit 40H shown in (b) in FIG. 12 further includes a third switching element 73 in addition to the configuration of the second current removal unit 40C shown in (a) in FIG. 8. The third switching element 73 is connected in series with the second resistance element 72 between the signal output terminal 22 of the current-to-voltage conversion unit 20 and the smoothing capacitor 42, more specifically, between the signal output terminal 22 and the node N6. The third switching element 73 switches the relationship between the signal output terminal 22 and the smoothing capacitor 42 between a connecting state and a disconnecting state. In the shown example, the third switching element 73 is connected between the signal output terminal 22 and the second resistance element 72, but the third switching element 73 may be connected between the second resistance element 72 and the node N6. In one example, the third switching element 73 includes a switch 73a. The switch 73a may be a mechanical switch or a semiconductor switch such as a transistor. The switching operation of the third switching element 73 is controlled by the control unit 50.

According to the second current removal unit 40H, when accumulating the charge in advance in the smoothing capacitor 42, the third switching element 73 can be made to have a disconnecting state. In this manner, it is possible to prevent a part of the current from the photodetection element 10 from flowing out through the second resistance element 72. Therefore, the charge can be efficiently accumulated in the smoothing capacitor 42.

The second current removal unit 40J shown in FIG. 13 has a feedback circuit section 41D instead of the feedback circuit section 41 in the above embodiment. The configuration other than the feedback circuit section 41D is the same as that of the second current removal unit 40 in the above embodiment. The feedback circuit section 41D in this modification includes a transistor 74. The transistor 74 is, for example, a MOSFET. One current terminal (for example, a source) of the transistor 74 is connected to the signal output terminal 22 of the current-to-voltage conversion unit 20. The other current terminal (for example, a drain) of the transistor 74 is connected to one electrode of the smoothing capacitor 42 through the node N6. The control terminal (gate) of the transistor 74 is electrically connected to the control unit 50, and receives a control signal from the control unit 50. The transistor 74 is in either a first state or a second state in response to a control signal input to the control terminal. The first state is a state in which the second signal voltage V2 is output. The second state is a state in which the output terminal is in a high impedance state and a signal at the input terminal is not transferred to the output terminal. According to this modification, when accumulating the charge in advance in the smoothing capacitor 42, it is possible to control the transistor 74 so that the output terminal is set to have a high impedance state and the signal at the input terminal is not transferred to the output terminal. Thus, this prevents a part of the current from the photodetection element 10 from flowing out through the transistor 74, the charge can be efficiently accumulated in the smoothing capacitor 42.

### Fifth Modification

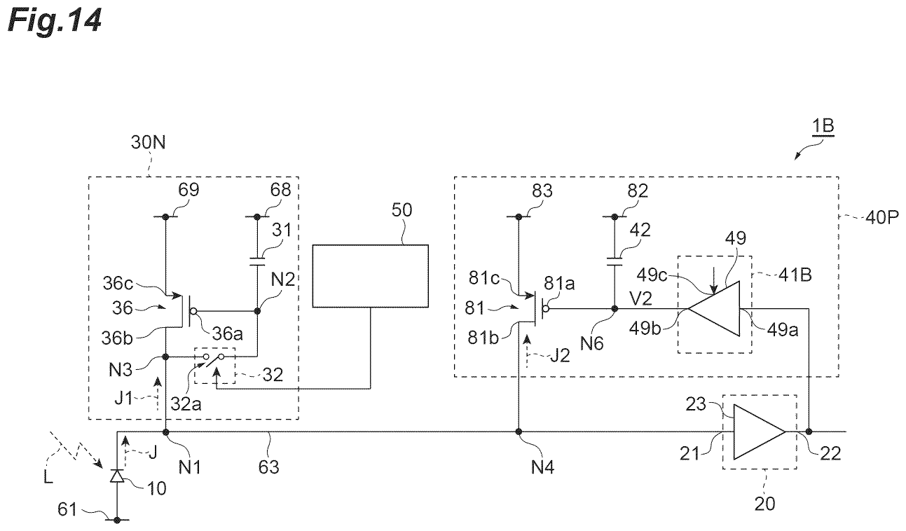

FIG. 14 is a circuit diagram showing the configuration of a photodetection circuit 1B according to a modification of the above embodiment. In this modification, the configuration of the current-to-voltage conversion unit 20 is similar to that in the above embodiment. In the photodetection circuit 1B according to this modification, the wiring 63 is connected to the cathode of the photodetection element 10, and the bias line 61 is connected to the anode of the photodetection element 10. The photodetection circuit 1B includes a first current removal unit 30N instead of the first current removal unit 30 in the above embodiment. The photodetection circuit 1B includes a second current removal unit 40P instead of the second current removal unit 40 in the above embodiment.

The first current removal unit 30N in this modification has a voltage-holding capacitor 31, a first switching element 32, and a first transistor 36. The voltage-holding capacitor 31 is configured to be charged by a current from the photodetection element 10. Specifically, one electrode of the voltage-holding capacitor 31 is connected to the photodetection element 10 through the first switching element 32 and a node N1. The other electrode of the voltage-holding capacitor 31 is connected to a sixth constant potential line 68. The potential of the sixth constant potential line 68 is higher than the potential of the bias line 61. The first switching element 32 is connected in series between the node N1 and the voltage-holding capacitor 31. The first switching element 32 switches on/off the flow of a current from the photodetection element 10 to the voltage-holding capacitor 31.

The first transistor 36 is configured to extract, from the signal current J, the first current J1 having a magnitude corresponding to the voltage across the voltage-holding capacitor 31. The first transistor 36 has a control terminal 36a (gate), a first current terminal 36b (drain), and a second current terminal 36c (source). The first transistor 36 in this modification is a P-channel MOSFET. The control terminal 36a is connected to the node N2 between one electrode of the voltage-holding capacitor 31 and the first switching element 32. A voltage based on the voltage across the voltage-holding capacitor 31, for example, the voltage across the voltage-holding capacitor 31 itself, is applied to the control terminal 36a. The first current terminal 36b is connected to the node N3 between the first switching element 32 and the node N1, and is connected to the photodetection element 10 through the nodes N3 and N1. The second current terminal 36c is connected to a seventh constant potential line 69. The potential of the seventh constant potential line 69 is higher than the potential of the bias line 61. The potential of the seventh constant potential line 69 may be the same as or different from the potential of the sixth constant potential line 68.

The second current removal unit 40P in this modification has a feedback circuit section 41B, a smoothing capacitor 42, and a second transistor 81. The configuration of the feedback circuit section 41B is similar to the configuration of the feedback circuit section 41B of the second current removal unit 40E shown in (a) in FIG. 9.

The smoothing capacitor 42 smooths the second signal voltage V2. The other electrode of the smoothing capacitor 42 in this modification is connected to a constant potential line 82. The potential of the constant potential line 82 is higher than the potential of the bias line 61.

The second transistor 81 is configured to extract, from the signal current J, the second current J2 having a magnitude corresponding to the second signal voltage V2 smoothed by the smoothing capacitor 42. The second transistor 81 has a control terminal 81a, a first current terminal 81b, and a second current terminal 81c. The second transistor 81 in this modification is a P-channel MOSFET. The control terminal 81a is connected to the node N6 between one electrode of the smoothing capacitor 42 and the feedback circuit section 41B. The second signal voltage V2 smoothed by the smoothing capacitor 42 is applied to the control terminal 81a. The first current terminal 81b is connected to the node N4, and is connected to the photodetection element 10 through the node N4. The second current terminal 81c is connected to a constant potential line 83. The potential of the constant potential line 83 may be the same as or different from the potential of the constant potential line 82. The gain of the second transistor 81 is lower than the gain of the first transistor 36, for example, 1/10 or less of the gain of the first transistor 36.

The photodetection circuit 1B according to this modification can also achieve the same effects as the photodetection circuit 1A according to the above embodiment.

### Sixth Modification

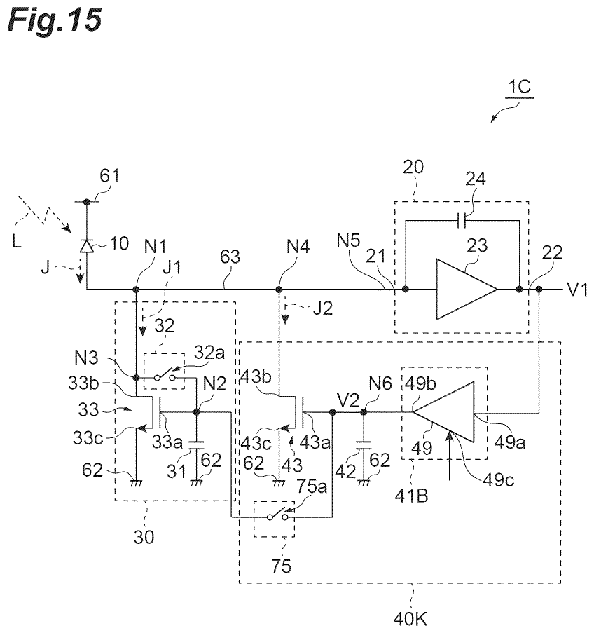

FIGS. 15 to 20 are circuit diagrams respectively showing the configurations of photodetection circuits 1C to 1H according to a modification of the above embodiment.

The photodetection circuit 1C shown in FIG. 15 includes a second current removal unit 40K instead of the second current removal unit 40 in the above embodiment. The second current removal unit 40K is different from the second current removal unit 40 in the following points, but is the same as the second current removal unit 40 in other points. The second current removal unit 40K has a second switching element 75 instead of the second switching element 45 of the second current removal unit 40. The second switching element 75 is connected in series with the first switching element 32 between the photodetection element 10 and the smoothing capacitor 42. That is, the second switching element 75 is connected in series between the node N2 and the node N6. The second switching element 75 switches on/off the flow of a current from the photodetection element 10 to the smoothing capacitor 42 together with the first switching element 32. The second switching element 75 in this modification has a switch 75a. The switch 75a may be a mechanical switch or a semiconductor switch such as a transistor. The switching operation of the second switching element 75 is controlled by the control unit 50. As in this second current removal unit 40K, the current supplied from the photodetection element 10 to the smoothing capacitor 42 may pass through the first switching element 32. Even in this case, the same effects as in the above embodiment can be achieved. The photodetection circuit 1C may include any one of the first current removal units 30 and 30A to 30N described above, and may include any one of the current-to-voltage conversion units 20 and 20A to 20D described above.

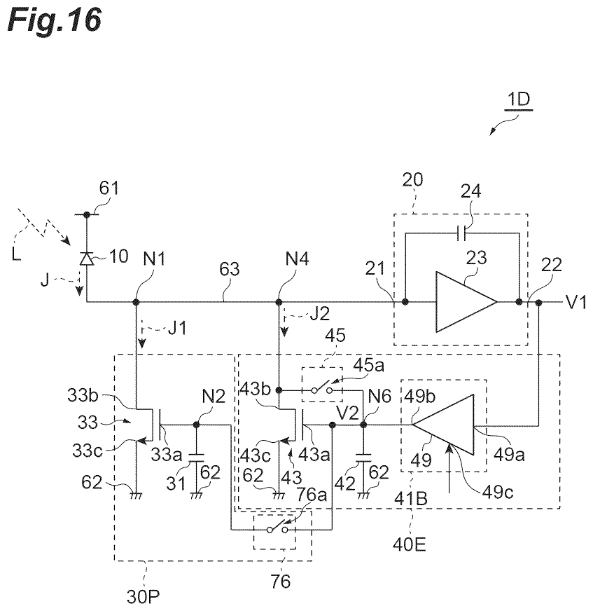

The photodetection circuit 1D shown in FIG. 16 includes a first current removal unit 30P instead of the first current removal unit 30 in the above embodiment. The first current removal unit 30P is different from the first current removal unit 30 in the following points, but is the same as the first current removal unit 30 in other points. The first current removal unit 30P has a first switching element 76 instead of the first switching element 32 of the first current removal unit 30. The first switching element 76 is connected in series with the second switching element 45 between the photodetection element 10 and the voltage-holding capacitor 31. That is, the first switching element 76 is connected in series between the node N6 and the node N2. The first switching element 76 switches on/off the flow of a current from the photodetection element 10 to the voltage-holding capacitor 31 together with the second switching element 45. The first switching element 76 in this modification has a switch 76a. The switch 76a may be a mechanical switch or a semiconductor switch such as a transistor. The switching operation of the first switching element 76 is controlled by the control unit 50. As in this first current removal unit 30P, the current supplied from the photodetection element 10 to the voltage-holding capacitor 31 may pass through the second switching element 45. Even in this case, the same effects as in the above embodiment can be achieved. The photodetection circuit 1D may include any one of the second current removal units 40 and 40A to 40J described above, and may include any one of the current-to-voltage conversion units 20 and 20A to 20D described above.

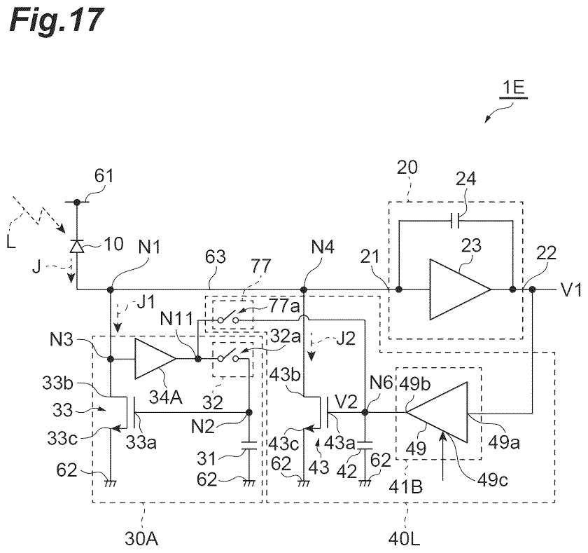

The photodetection circuit 1E shown in FIG. 17 includes any first current removal unit of the first current removal unit 30A shown in (a) in FIG. 3, the first current removal unit 30B shown in (b) in FIG. 3, and the first current removal unit 30C shown in (c) in FIG. 3, instead of the first current removal unit 30 in the above embodiment. In addition, the photodetection circuit 1E includes a second current removal unit 40L instead of the second current removal unit 40 in the above embodiment. The second current removal unit 40L is different from the second current removal unit 40 in the following points, but is the same as the second current removal unit 40 in other points. The second current removal unit 40L has a second switching element 77 instead of the second switching element 45 of the second current removal unit 40. The second switching element 77 is connected in series between the node N11 between the first amplifier 34A (or the first amplifier 34B) and the first switching element 32 and the node N6. The second switching element 77 switches on/off the flow of a current from the photodetection element 10 to the smoothing capacitor 42. The second switching element 77 in this modification has a switch 77a. The switch 77a may be a mechanical switch or a semiconductor switch such as a transistor. The switching operation of the second switching element 77 is controlled by the control unit 50.

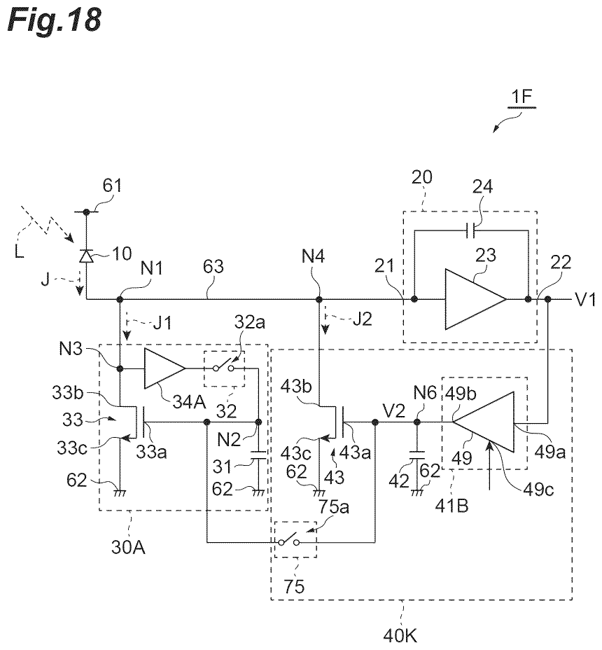

As in this second current removal unit 40L, the first amplifier 34A (or the first amplifier 34B) of the first current removal units 30A to 30C may also be used to amplify the current (or voltage) from the photodetection element 10 to the smoothing capacitor 42. In this case, both the effect obtained by the first current removal units 30A to 30C shown in (a) to (c) in FIG. 3 and the effect obtained by the second current removal unit 40D shown in (b) in FIG. 8 can be obtained with a smaller circuit. Similar effects can also be obtained by combining any one of the first current removal units 30A to 30C with the second current removal unit 40K shown in FIG. 15, as in the photodetection circuit 1F shown in FIG. 18.

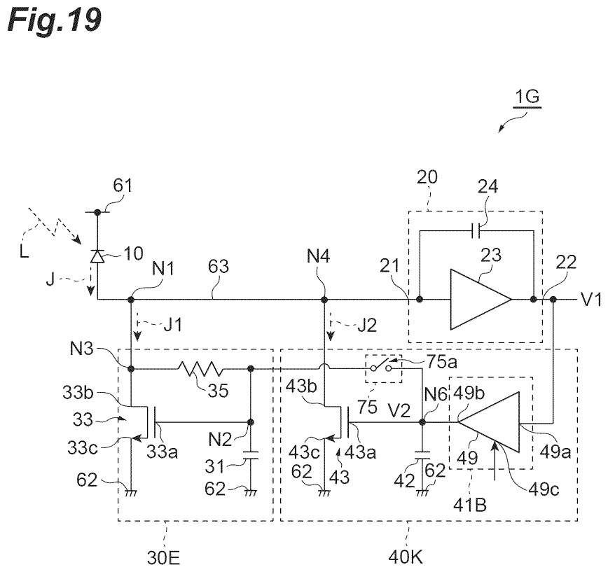

The photodetection circuit 1G shown in FIG. 19 has the first current removal unit 30E shown in (b) in FIG. 4 instead of the first current removal unit 30 in the above embodiment. In addition, the photodetection circuit 1G has the second current removal unit 40K shown in FIG. 15, instead of the second current removal unit 40 in the above embodiment. As in this photodetection circuit 1G, the current supplied from the photodetection element 10 to the smoothing capacitor 42 may pass through the first resistance element 35. Even in this case, the same effects as in the above embodiment can be achieved.

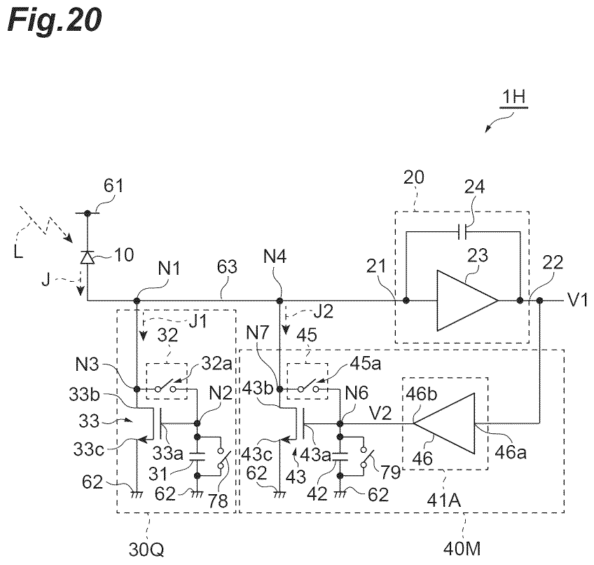

The photodetection circuit 1H shown in FIG. 20 has a first current removal unit 30Q instead of the first current removal unit 30 in the above embodiment. The first current removal unit 30Q further has a first shorting switch 78 in addition to the configuration of any one of the first current removal units 30 and 30A to 30P. The first shorting switch 78 is connected in parallel with the voltage-holding capacitor 31 between the node N2 and the reference potential line 62. When the first current removal unit 30Q is not in use, the pair of electrodes of the voltage-holding capacitor 31 may be shorted through the first shorting switch 78. Therefore, it is possible to prevent the misoperation of the first transistor 33 due to unnecessary accumulation of charge in the voltage-holding capacitor 31.

The photodetection circuit 1H has a second current removal unit 40M instead of the second current removal unit 40 in the above embodiment. The second current removal unit 40M further has a second shorting switch 79 in addition to the configuration of any one of the second current removal units 40 and 40A to 40L. The second shorting switch 79 is connected in parallel with the smoothing capacitor 42 between the node N6 and the reference potential line 62. When the second current removal unit 40M is not in use, the pair of electrodes of the smoothing capacitor 42 may be shorted through the second shorting switch 79. Therefore, since the control terminal 43a of the second transistor 43 is connected to the reference potential line 62 through the second shorting switch 79, the misoperation of the second transistor 43 can be prevented.

The photodetection circuit according to the present disclosure is not limited to the above-described embodiment, and various other modifications can be made. For example, the respective modifications described above may be combined according to the required purpose and effect. The second switching element of the second current removal unit may be omitted depending on the situation.

### Supplementary Note

In the photodetection circuit, when extracting a low-frequency component from the signal current with a feedback circuit, the feedback circuit is required to shorten the settling time of the feedback operation. Therefore, the photodetection circuit may have the following configuration.

A photodetection circuit, including:
a photodetection element that outputs a signal current in response to the incidence of signal light;
a current-to-voltage conversion unit that has a signal input terminal and a signal output terminal and that converts the signal current input to the signal input terminal into a first signal voltage and outputs the first signal voltage from the signal output terminal, the signal input terminal being connected to the photodetection element; and
a current removal unit connected to the photodetection element,
wherein the signal current includes a signal component and a low-frequency component having a lower frequency than the signal component or having a constant magnitude, and
the current removal unit includes:
a feedback circuit section that is connected to the signal output terminal of the current-to-voltage conversion unit and outputs a second signal voltage having a magnitude corresponding to the first signal voltage;
a smoothing capacitor configured to smooth the second signal voltage;
a second transistor configured to extract, from the signal current, the low-frequency component having a magnitude corresponding to the second signal voltage smoothed by the smoothing capacitor; and
a switching element connected in series between the photodetection element and the smoothing capacitor and configured to switch on/off a flow of a current from the photodetection element to the smoothing capacitor.

The photodetection circuit operates, for example, as follows. First, in a period during which the first signal voltage output from the photodetection circuit is not used outside the photodetection circuit, the switching element allows a current to flow from the photodetection element to the smoothing capacitor. As a result, the charge is accumulated in the smoothing capacitor, and the voltage across the smoothing capacitor increases. Thereafter, the first signal voltage output from the photodetection circuit is used outside the photodetection circuit. At that time, the switching element is switched so that no current flows from the photodetection element to the smoothing capacitor. Therefore, the smoothing capacitor can smooth the second signal voltage. Thus, according to the photodetection circuit described above, the charge can be accumulated in advance in the smoothing capacitor before the first signal voltage is used outside the photodetection circuit. Therefore, the settling time of the feedback operation in the current removal unit can be shortened.

### REFERENCE SIGNS LIST

1A to 1H: photodetection circuit, 10: photodetection element, 20, 20A to 20D: current-to-voltage conversion unit, 21: signal input terminal, 22: signal output terminal, 23: amplifier, 24: capacitor, 25: resistor, 26, 27: fourth switching element, 26a, 27a: switch, 28: amplifier, 28a: control terminal, 30, 30A to 30H, 30J to 30N, 30P, 30Q: first current removal unit, 31: voltage-holding capacitor, 32, 76: first switching element, 32a, 76a: switch, 32A: first switching element, 33, 36: first transistor, 33a, 36a: control terminal, 33b, 36b: first current terminal, 33c, 36c: second current terminal, 34A, 34B: first amplifier, 35: first resistance element, 37A, 37B: first amplifier, 38: transistor, 38a: control terminal, 38b: first current terminal, 38c: second current terminal, 39: source follower circuit, 40, 40A to 40F, 40H, 40J to 40M, 40P: second current removal unit, 41, 41A to 41D: feedback circuit section, 42: smoothing capacitor, 43, 81: second transistor, 43a, 81a: control terminal, 43b, 81b: first current terminal, 43c, 81c: second current terminal, 44, 46: second amplifier, 44a: first input terminal, 44b: second input terminal, 44c: output terminal, 45, 75, 77: second switching element, 45a, 75a, 77a: switch, 46, 49: second amplifier, 46a, 49a: input terminal, 46b, 49b: output terminal, 47: second resistance element, 48: third amplifier, 49c: control terminal, 50: control unit, 61: bias line, 62: reference potential line, 63: wiring, 64: third constant potential line, 65: fourth constant potential line, 66: fifth constant potential line, 68: sixth constant potential line, 69: seventh constant potential line, 71, 73: third switching element, 71a, 73a: switch, 72: second resistance element, 74: transistor, 78: first shorting switch, 79: second shorting switch, 82, 83: constant potential line, 311: resistance element, 321: amplifier, 391: transistor, 392: current source, 421: resistance element, J: signal current, J1: first current, J2: second current, L: signal light, N1 to N11: node, V1: first signal voltage, V2: second signal voltage, Vref1, Vref2, Vref3: reference voltage.

1. A photodetection circuit, comprising:
a photodetector configured to output a signal current in response to incidence of signal light;
a current-to-voltage converter having a signal input terminal and a signal output terminal and configured to convert the signal current input to the signal input terminal into a first signal voltage and output the first signal voltage from the signal output terminal, the signal input terminal being connected to the photodetector;
a first current removal circuit connected to the photodetector and configured to extract a first current from the signal current; and
a second current removal circuit connected to the photodetector and configured to extract a second current from the signal current,
wherein the signal current includes a signal component and a low-frequency component having a lower frequency than the signal component or having a constant magnitude, the first current removal circuit is configured to determine a magnitude of the first current based on the magnitude of the low-frequency component at a predetermined timing and to maintain the magnitude of the first current, and
the second current removal circuit includes:
a feedback circuit connected to the signal output terminal of the current-to-voltage converter and configured to output a second signal voltage having a magnitude corresponding to the first signal voltage;
a smoothing capacitor configured to smooth the second signal voltage; and
a second transistor configured to extract, from the signal current, the second current having a magnitude corresponding to the second signal voltage smoothed by the smoothing capacitor.

2. The photodetection circuit according to claim 1,
wherein the first current removal circuit includes:
a voltage-holding capacitor configured to be charged by a current from the photodetector;
a first switch configured to switch on/off a flow of a current from the photodetector to the voltage-holding capacitor; and
a first transistor having a control terminal, a first current terminal, and a second current terminal, a voltage based on a voltage across the voltage-holding capacitor being applied to the control terminal, the first current terminal being connected to the photodetector, and the second current terminal being connected to a constant potential line.

3. The photodetection circuit according to claim 2,
wherein the first switch is an amplifier having a control terminal for selecting whether or not to perform output.

4. The photodetection circuit according to claim 1,
wherein the first current removal circuit includes:
a voltage-holding capacitor configured to be charged by a current from the photodetector;
a first resistor provided on a path of a current flowing from the photodetector to the voltage-holding capacitor; and
a first transistor having a control terminal, a first current terminal, and a second current terminal, a voltage based on a voltage across the voltage-holding capacitor being applied to the control terminal, the first current terminal being connected to the photodetector, and the second current terminal being connected to a constant potential line.

5. The photodetection circuit according to claim 2,
wherein the first current removal circuit further includes a first amplifier configured to amplify a current flowing from the photodetector to the voltage-holding capacitor or a voltage applied from the photodetector to the voltage-holding capacitor.

6. The photodetection circuit according to claim 2,
wherein the first current removal circuit further includes a transistor connected in series with the first transistor between the photodetector and the constant potential line and having a control terminal to which a voltage based on a voltage across the voltage-holding capacitor is applied.

7. The photodetection circuit according to claim 2,
wherein the first current removal circuit further includes a first shorting switch connected in parallel with the voltage-holding capacitor.

8. The photodetection circuit according to claim 1,
wherein the second current removal circuit further includes a second switch connected in series between the photodetector and the smoothing capacitor and configured to switch on/off a flow of a current from the photodetector to the smoothing capacitor.

9. The photodetection circuit according to claim 8,
wherein the feedback circuit includes a second amplifier having an input terminal and an output terminal, the input terminal being connected to the signal output terminal of the current-to-voltage converter and the output terminal being connected to the smoothing capacitor, and
the second amplifier further has a control terminal for selecting whether or not to perform output.

10. The photodetection circuit according to claim 8,
wherein the feedback circuit includes a second amplifier having an input terminal and an output terminal, the input terminal being connected to the signal output terminal of the current-to-voltage converter and the output terminal being connected to the smoothing capacitor, and
the second current removal circuit further includes a third switch that is connected in series between the second amplifier and the smoothing capacitor and switches a relationship between the second amplifier and the smoothing capacitor between a connecting state and a disconnecting state.

11. The photodetection circuit according to claim 8,
wherein the feedback circuit includes a second resistor having one end and another end, the one end being connected to the signal output terminal of the current-to-voltage converter and the another end being connected to the smoothing capacitor, and
the second current removal circuit further includes a third switch that is connected in series with the second resistor between the signal output terminal of the current-to-voltage converter and the smoothing capacitor and switches a relationship between the signal output terminal and the smoothing capacitor between a connecting state and a disconnecting state.

12. The photodetection circuit according to claim 8,
wherein the second current removal circuit further includes a third amplifier configured to amplify a current flowing from the photodetector to the smoothing capacitor or a voltage applied from the photodetector to the smoothing capacitor.

13. The photodetection circuit according to claim 8,
wherein the second switch is an amplifier having a control terminal for selecting whether or not to perform output.

14. The photodetection circuit according to claim 8,
wherein the current-to-voltage converter is configured to be able to switch on/off input of the signal current to the signal input terminal.

15. The photodetection circuit according to claim 2,
wherein the second current removal circuit further includes a second switch connected in series between a node between the first switch and the voltage-holding capacitor and the smoothing capacitor and configured to switch on/off a flow of a current from the photodetector to the smoothing capacitor together with the first switch.

16. The photodetection circuit according to claim 2,
wherein the second current removal circuit further includes a second switch connected in series between the photodetector and the smoothing capacitor and configured to switch on/off a flow of a current from the photodetector to the smoothing capacitor, and
the first switch is connected in series between a node between the second switch and the smoothing capacitor and the voltage-holding capacitor and is configured to switch on/off a flow of a current from the photodetector to the voltage-holding capacitor together with the second switch.

17. The photodetection circuit according to claim 1,
wherein the second current removal circuit further includes a second shorting switch connected in parallel with the smoothing capacitor.

18. The photodetection circuit according to claim 4,
wherein the first current removal circuit further includes a first amplifier configured to amplify a current flowing from the photodetector to the voltage-holding capacitor or a voltage applied from the photodetector to the voltage-holding capacitor.

19. The photodetection circuit according to claim 4,
wherein the first current removal circuit further includes a transistor connected in series with the first transistor between the photodetector and the constant potential line and having a control terminal to which a voltage based on a voltage across the voltage-holding capacitor is applied.

20. The photodetection circuit according to claim 4,
wherein the first current removal circuit further includes a first shorting switch connected in parallel with the voltage-holding capacitor.
